(19) United States
(12) Patent Application Publication
(10) Pub. No.: US 2026/0087955 A1
(43) Pub. Date: Mar. 26, 2026

(54) DISPLAY APPARATUS AND ELECTRONIC APPARATUS INCLUDING THE SAME

(71) Applicant: Samsung Display Co., Ltd., Yongin-si (KR)

(72) Inventors: Younjoo Lee, Yongin-si (KR); Seungjun Lee, Yongin-si (KR)

(21) Appl. No.: 19/300,263

(22) Filed: Aug. 14, 2025

(30) Foreign Application Priority Data
Sep. 23, 2024 (KR) 10-2024-0128265

(51) Int. Cl. G09G 3/00; G09G 3/32; G09G 3/3233

(52) U.S. Cl. CPC G09G 3/035; G09G 3/32; G09G 3/3233; G09G 2320/0242

(57) ABSTRACT

A display apparatus includes a plurality of first regions spaced from each other in a first direction and a second direction crossing the first direction, and a second region connecting the plurality of first regions includes a substrate, a plurality of light-emitting elements over the substrate and overlapping the plurality of first regions, and a strain sensor layer overlapping the plurality of light-emitting elements.

### CROSS-REFERENCE TO RELATED APPLICATION

This application claims priority to and the benefit of Korean Patent Application No. 10-2024-0128265, filed on Sep. 23, 2024, in the Korean Intellectual Property Office, the entire disclosure of which is incorporated by reference herein.

### BACKGROUND

### 1. Field

One or more embodiments relate to a display apparatus and an electronic apparatus including the same.

### 2. Description of the Related Art

Generally, as a display panel that visually displays various electrical signals develops, various display panels having excellent characteristics such as being slim, being lightweight, low power consumption, and/or the like, and electronic apparatuses including the display panels have been introduced. As an example, research into display panels having various structures, such as flexible display panels that are foldable, rollable in a roll shape, and/or stretchable display panels, and electronic apparatuses including the display panels has been actively carried out.

### SUMMARY

One or more embodiments of the present disclosure include a display apparatus having improved stretchability and configured to implement high-quality images, and an electronic apparatus including the display apparatus. However, such a technical objective is just an example, and the present disclosure is not limited thereto.

Additional aspects will be set forth in part in the description that follows and, in part, will be apparent from the description, or may be learned by practice of embodiments of the present disclosure.

According to one or more embodiments, a display apparatus including a plurality of first regions spaced from each other in a first direction and a second direction crossing the first direction, and a second region connecting the plurality of first regions includes a substrate, a plurality of light-emitting elements over the substrate and overlapping the plurality of first regions, and a strain sensor layer overlapping the plurality of light-emitting elements, wherein the second region includes a plurality of second-1 regions connecting two first regions of the plurality of first regions spaced from each other in the first direction, and a plurality of second-2 regions connecting two first regions of the plurality of first regions spaced from each other in the second direction, and wherein the strain sensor layer includes a first sensing line configured to sense stretching of the substrate in the first direction, extending in the first direction, and overlapping each of the plurality of first regions and the plurality of second-1 regions.

In one or more embodiments, the first sensing line may be spaced from the plurality of second-2 regions in a plan view.

In one or more embodiments, the plurality of first regions may be located symmetrically with respect to a first central line extending in the first direction and a second central line extending in the second direction.

In one or more embodiments, the first sensing line includes a plurality of first sensing lines, and at least one of the plurality of first regions may be spaced from the plurality of first sensing lines in a plan view.

In one or more embodiments, the plurality of first sensing lines may be located symmetrically with respect to a first central line extending in the first direction and a second central line extending in the second direction.

In one or more embodiments, the strain sensor layer may further include a second sensing line configured to sense stretching of the substate in the first direction, extending in the second direction, and overlapping the plurality of second-1 regions.

In one or more embodiments, the second sensing line may be spaced from each of the plurality of first regions and the plurality of second-2 regions in a plan view.

In one or more embodiments, the first sensing line and the second sensing line may cross each other in the plurality of second-1 regions in a plan view.

In one or more embodiments, the second sensing line includes a plurality of second sensing lines, and at least one of the plurality of second-1 regions may be spaced from the plurality of second sensing lines in a plan view.

In one or more embodiments, the strain sensor layer may further include a second sensing line configured to sense stretching of the substate in the second direction, extending in the second direction, and overlapping each of the plurality of first regions and the plurality of second-2 regions.

In one or more embodiments, the second sensing line may be spaced from the plurality of second-1 regions in a plan view.

In one or more embodiments, the first sensing line and the second sensing line may cross each other in the plurality of first regions in a plan view.

According to one or more embodiments, an electronic apparatus including a display apparatus including a plurality of first regions spaced from each other in a first direction and a second direction crossing the first direction, and a second region connecting the plurality of first regions includes a substrate, a plurality of light-emitting elements over the substrate and overlapping the plurality of first regions, and a strain sensor layer on the plurality of light-emitting elements, wherein the second region includes a plurality of second-1 regions connecting two first regions of the plurality of first regions spaced from each other in the first direction, and a plurality of second-2 regions connecting two first regions of the plurality of first regions spaced from each other in the second direction, wherein the strain sensor layer includes a first sensing line configured to sense stretching of the substrate in the first direction and extending in the first direction, and a second sensing line configured to sense stretching of the substrate in the first direction and extending in the second direction, and wherein the first sensing line and the second sensing line cross each other in the plurality of second-1 regions.

In one or more embodiments, each of the first sensing line and the second sensing line may be spaced from the plurality of second-2 regions.

In one or more embodiments, the first sensing line includes a plurality of first sensing lines that are spaced from each other in the second direction, and the second sensing line includes a plurality of second sensing lines that are spaced from each other in the first direction.

In one or more embodiments, at least one of the plurality of first regions may be spaced from the plurality of first sensing lines in a plan view.

In one or more embodiments, at least one of the plurality of second-1 regions may be spaced from the plurality of second sensing lines in a plan view.

According to one or more embodiments, an electronic apparatus including a display apparatus including a plurality of first regions spaced from each other in a first direction and a second direction crossing the first direction, and a second region connecting the plurality of first regions includes a substrate, a plurality of light-emitting elements over the substrate and overlapping the plurality of first regions, and a strain sensor layer on the plurality of light-emitting elements, wherein the second region includes a plurality of second-1 regions connecting two first regions of the plurality of first regions spaced from each other in the first direction, and a plurality of second-2 regions connecting two first regions of the plurality of first regions spaced from each other in the second direction, wherein the strain sensor layer includes a first sensing line configured to sense stretching of the substrate in the first direction and extending in the first direction, and a second sensing line configured to sense stretching of the substrate in the second direction and extending in the second direction, and wherein the first sensing line and the second sensing line cross each other in the plurality of first regions.

In one or more embodiments, the second region may further include a plurality of second-3 regions between the plurality of second-1 regions and the plurality of second-2 regions, and each of the first sensing line and the second sensing line may be spaced from the plurality of second-3 regions.

In one or more embodiments, the first sensing line includes a plurality of first sensing lines that are spaced from each other in the second direction, and the second sensing line includes a plurality of second sensing lines that are spaced from each other in the first direction.

These and/or other aspects will become apparent and more readily appreciated from the following detailed description of the embodiments, the accompanying drawings, and claims.

### BRIEF DESCRIPTION OF THE DRAWINGS

The above and other aspects and features of embodiments of the present disclosure will be more apparent from the following description taken in conjunction with the accompanying drawings, in which:

FIG. 1 is a schematic perspective view of a display apparatus according to one or more embodiments;

FIGS. 2A and 2B are perspective views of the display apparatus of FIG. 1 in a state stretched in a first direction;

FIG. 2C is a perspective view showing a state in which the display apparatus of FIG. 1 is stretched in a second direction;

FIG. 2D is a perspective view showing a state in which the display apparatus of FIG. 1 is stretched in the first direction and the second direction;

FIG. 2E is a perspective view showing a state in which the display apparatus of FIG. 1 is stretched in a third direction;

FIG. 3 is a schematic block diagram of a display apparatus according to one or more embodiments;

FIGS. 4A, 4B, and 4C are equivalent circuit diagrams of a pixel included in a display apparatus according to one or more embodiments;

FIGS. 5A and 5B are schematic cross-sectional views of the display apparatus shown in FIG. 1, taken along the line I-I′ of FIG. 1;

FIG. 6 is a schematic cross-sectional view of a portion of a display panel according to one or more embodiments;

FIGS. 7A and 7B are schematic cross-sectional views of a light-emitting element of a display apparatus according to one or more embodiments;

FIGS. 8A and 8B are schematic plan views of a portion of a display area according to one or more embodiments;

FIGS. 9A and 9B are schematic plan views of a strain sensor layer according to one or more embodiments;

FIG. 10 is a schematic view of a strain sensor layer and a stretching compensation portion according to one or more embodiments;

FIG. 11 is a schematic view to explain an operation of a stretching compensation portion according to one or more embodiments;

FIGS. 12A and 12B are schematic plan views of a portion of a display panel according to one or more embodiments;

FIG. 13 is a schematic plan view of a portion of a display panel according to one or more embodiments;

FIG. 14 is a schematic plan view of a portion of a display panel according to one or more embodiments;

FIG. 15 is a schematic plan view of a portion of a display panel according to one or more embodiments;

FIG. 16A-16D are schematic plan views of a portion of a display panel according to one or more embodiments;

FIG. 17 is a schematic plan view of a portion of a display panel according to one or more embodiments;

FIG. 18 is a schematic plan view of a portion of a display panel according to one or more embodiments; and

FIG. 19A-19G are schematic perspective views of electronic apparatuses including a display panel according to one or more embodiments.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, embodiments are merely described below, by referring to the figures, to explain aspects and features of the present disclosure. As used herein, the term “and/or” includes any and all combinations of one or more of the associated listed items. Throughout the present disclosure, the expression “at least one of a, b or c” (or “at least one of a, b and c”) indicates only a, only b, only c, both a and b, both a and c, both b and c, all of a, b, and c, or variations thereof.

As the present disclosure allows for various changes and numerous embodiments, certain embodiments will be illustrated in the drawings and described in the written description. Effects, aspects, and features of the present disclosure, and methods for achieving them will be clarified with reference to embodiments described below in detail with reference to the drawings. However, the present disclosure is not limited to the following embodiments and may be embodied in various forms.

Hereinafter, embodiments will be described with reference to the accompanying drawings, wherein like reference numerals refer to like elements throughout and a repeated description thereof is omitted.

While such terms as “first” and “second” may be used to describe various elements, such elements must not be limited to the above terms. The above terms are used to distinguish one element from another.

The singular forms “a,” “an,” and “the” as used herein are intended to include the plural forms as well unless the context clearly indicates otherwise.

It will be understood that the terms “comprise,” “comprising,” “include” and/or “including” as used herein specify the presence of stated features or elements but do not preclude the addition of one or more other features or elements.

It will be further understood that, when a layer, region, or element is referred to as being “on” another layer, region, or element, it can be directly or indirectly on the other layer, region, or element. That is, for example, intervening layers, regions, or elements may be present.

Sizes of elements in the drawings may be exaggerated or reduced for convenience of explanation. As an example, the size and thickness of each element shown in the drawings are arbitrarily represented for convenience of description, and thus, the present disclosure is not necessarily limited thereto.

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

In the case where a certain embodiment may be implemented differently, a specific process order may be performed in the order different from the described order. As an example, two processes successively described may be concurrently (e.g., simultaneously) performed substantially and performed in the opposite order.

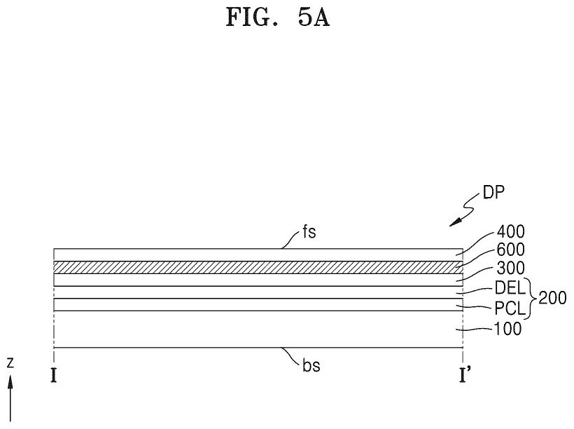

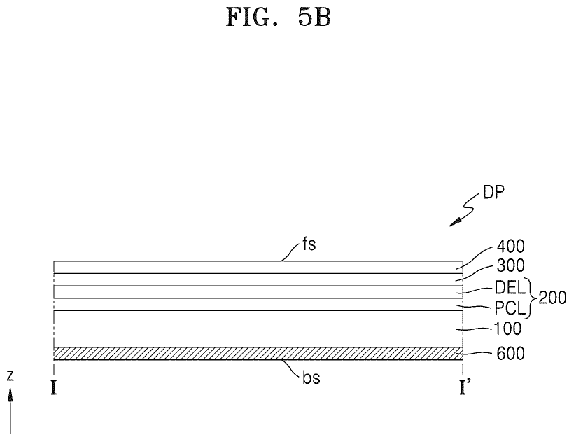

In the present specification, “on a plane” or “in a plan view” means a plane viewed from a direction perpendicular to a substrate 100 (see FIG. 5A). That is, “A and B spaced from each other on a plane or in a plan view” means “A and B spaced from each other when viewed in a direction perpendicular to the substrate 100 (see FIG. 5A).”

In the present specification, “in a cross-section” means a plane cut in a direction perpendicular to the substrate 100 (see FIG. 5A). That is, “A and B spaced from each other on a plane in a cross-section” means “A and B spaced from each other in a plane cut in a direction perpendicular to the substrate 100 (see FIG. 5A).”

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

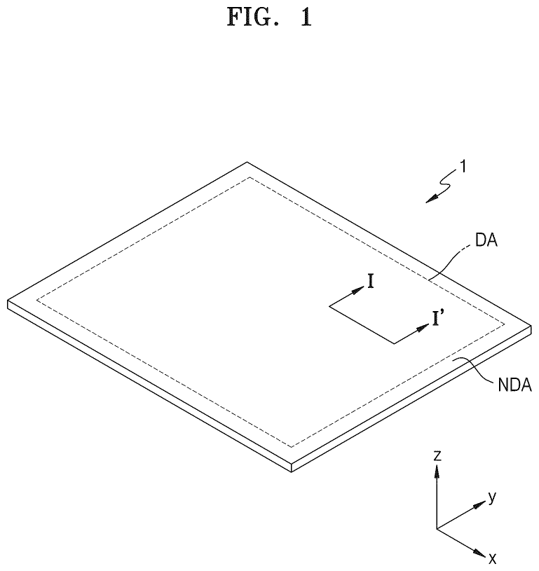

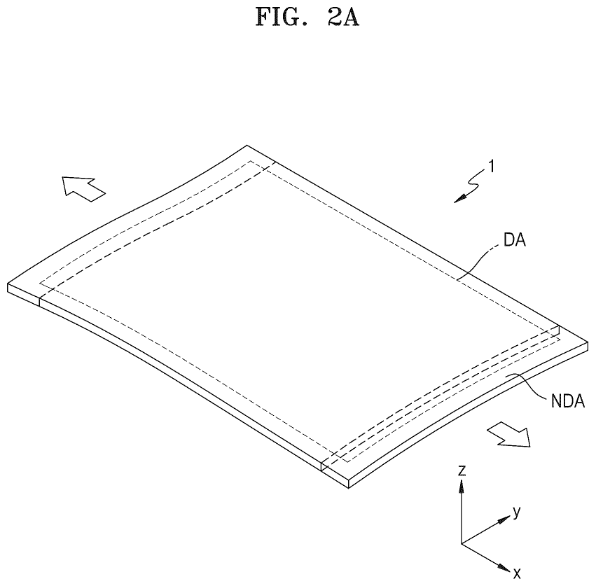

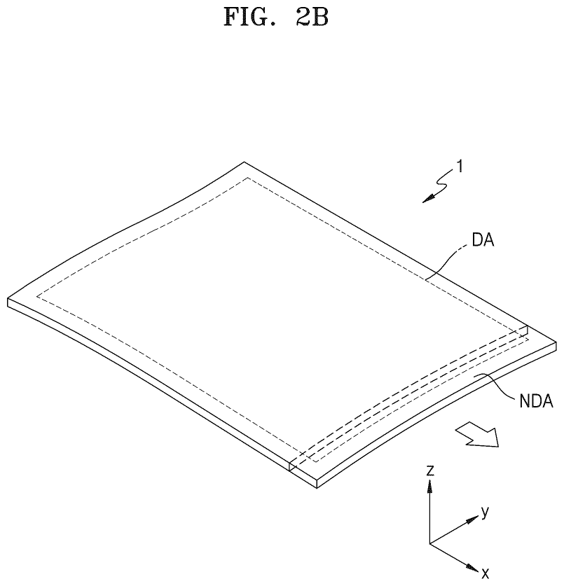

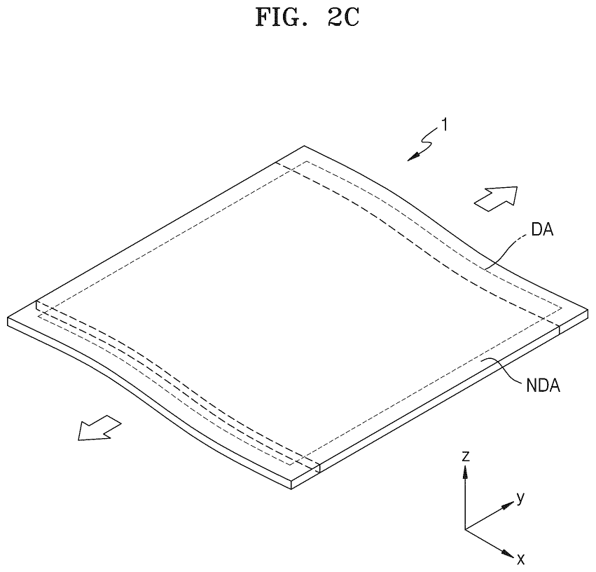

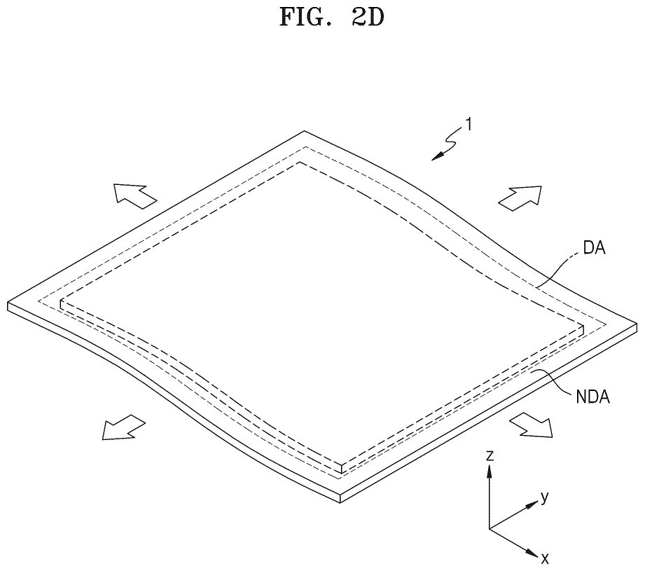

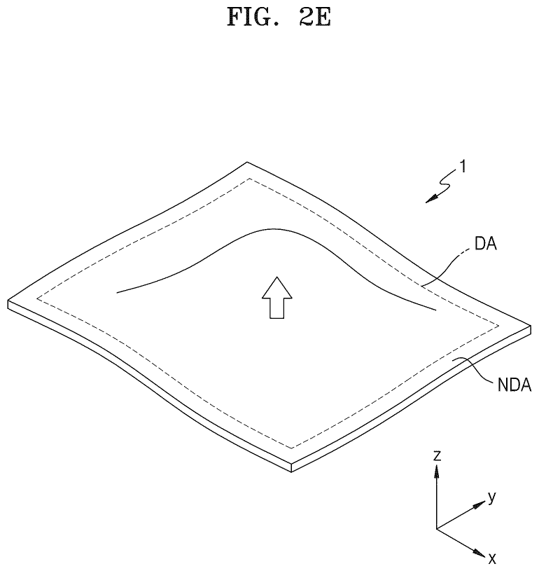

FIG. 1 is a schematic perspective view of a display apparatus 1 according to one or more embodiments. FIGS. 2A and 2B are perspective views of the display apparatus 1 of FIG. 1 in a state stretched in a first direction. FIG. 2C is a perspective view showing a state in which the display apparatus 1 of FIG. 1 is stretched in a second direction. FIG. 2D is a perspective view showing a state in which the display apparatus 1 of FIG. 1 is stretched in the first direction and the second direction. FIG. 2E is a perspective view showing a state in which the display apparatus 1 of FIG. 1 is stretched in a third direction.

Referring to FIG. 1, the display apparatus 1 may be a stretchable display apparatus that may stretch and/or shrink in various directions. The display apparatus 1 may include a display area DA and a non-display area NDA around an edge or a periphery of the display area DA. The display area DA may include a plurality of pixels. The display apparatus 1 may be configured to display images by using light emitted from the plurality of pixels. The non-display area NDA may be disposed outside the display area DA and denoted as a peripheral area. The non-display area NDA may surround the display area DA entirely.

The display apparatus 1 may be stretched in the first direction (e.g., x direction and/or −x direction) by external force exerted by an external object and/or a user. In one or more embodiments, as shown in FIGS. 2A and 2B, the display area DA and/or the non-display area NDA of the display apparatus 1 may be stretched in the first direction (e.g., x direction and/or −x direction). As an example, as shown in FIG. 2A, the display apparatus 1 may be stretched in the x direction and −x direction, or stretched in the x direction or −x direction with one side of the display apparatus 1 fixed. FIG. 2B shows an example in which the display apparatus 1 is stretched in the x direction with one side of the display apparatus 1 fixed.

The display apparatus 1 may be stretched in the second direction (e.g., y direction and/or −y direction) by external force exerted by an external object and/or a user. In one or more embodiments, as shown in FIG. 2C, the display area DA and/or the non-display area NDA of the display apparatus 1 may be stretched in the y direction and −y direction. In another embodiment, the display apparatus 1 may be stretched in the y direction or −y direction with one side of the display apparatus 1 fixed.

The display apparatus 1 may be stretched in a plurality of directions, for example, the first direction (e.g., x direction and/or −x direction) and the second direction (e.g., y direction and/or −y direction) by external force exerted by an external object and/or a portion of a person's body. As shown in FIG. 2D, the display area DA and/or the non-display area NDA of the display apparatus 1 may be stretched in a ±x direction and ±y direction.

The display apparatus 1 may be stretched in a third direction (e.g., z direction and/or −z direction) by external force exerted by an external object and/or a portion of a person's body. In one or more embodiments, FIG. 2E shows a portion of the display apparatus 1, for example, a partial region of the display area DA protrudes in the z direction. In another embodiment, a portion of the display apparatus 1, for example, a partial region of the display area DA may protrude in the −z direction (or be recessed in the z direction).

Although it is shown in FIG. 2A-2E that the display apparatus 1 is stretched in the first direction, the second direction, and/or the third direction, the present disclosure is not limited thereto. In another embodiment, the display apparatus 1 may be variously transformed into an irregular shape, such as being bent and/or twisted along two or more axes. In another embodiment, the display apparatus 1 may be a foldable display apparatus that is foldable or un-foldable with respect to a folding axis extending in one direction, or a rollable display apparatus that is rollable or unrollable around a virtual axis.

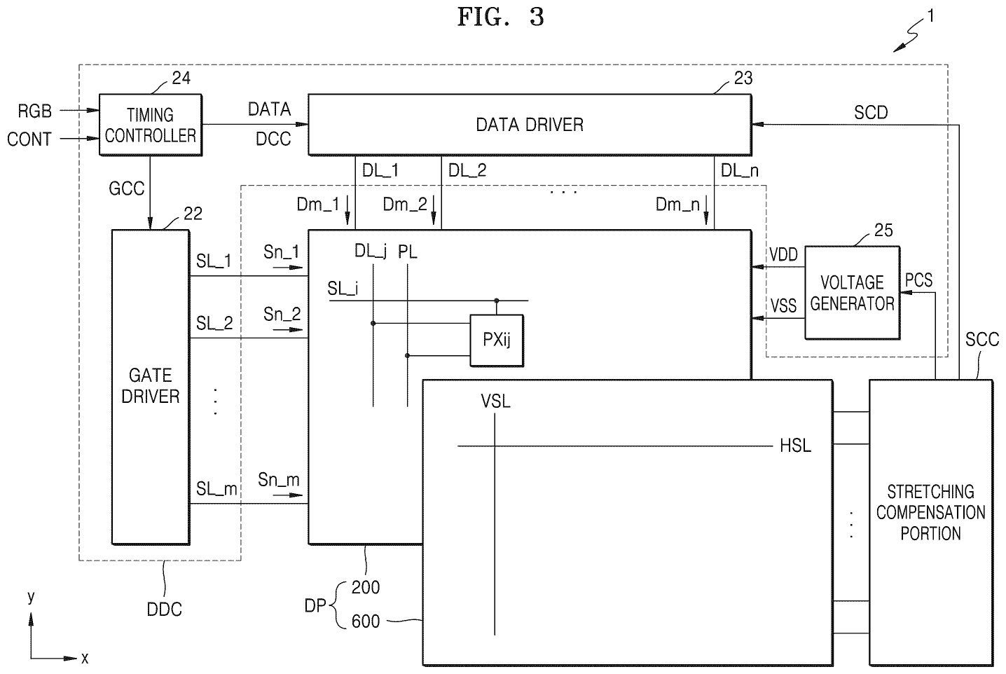

FIG. 3 is a schematic block diagram of the display apparatus 1 according to one or more embodiments.

Referring to FIG. 3, the display apparatus 1 may include a display panel DP, a display driver DDC, and a stretching compensation portion SCC. The display panel DP may include a display layer 200 and a strain sensor layer 600.

The display layer 200 may include pixels PX, scan lines SL_1 to SL_m, data lines DL_1 to DL_n, and power lines PL connected to the pixels PX. For easy understanding, although FIG. 3 shows only one pixel PXij located in an i-th row and a j-th column, m×n pixels may be arranged, for example, in a matrix configuration. Here, i is a natural number equal to or greater than 1 and equal to or less than m, and j is a natural number equal to or greater than 1 and equal to or less than n.

For an example purpose only, FIG. 3 mainly describes a pixel PX employing a pixel driving circuit portion including two transistors and one capacitor. However, the present disclosure is not only applicable to the pixel PX employing a specific pixel driving circuit portion but also equally applicable to a pixel PX employing another pixel driving circuit portion, for example, a pixel driving circuit portion including three transistors and one capacitor, and a pixel PX employing a pixel driving circuit portion including seven transistors and one capacitor.

The pixels PX are connected to the scan lines SL_1 to SL_m, the data lines DL_1 to DL_n, and the power line PL. As an example, the pixel PXij located in the i-th row and the j-th column may be connected to a scan line SL_i, a data line DL_j, and the power line PL.

The data lines DL_1 to DL_n may extend in the second direction (y direction) and may be connected to the pixels PX located in the same column. The scan lines SL_1 to SL_m may extend in the first direction (x direction) and may be connected to the pixels PX located in the same row. The power lines PL may extend in the second direction (y direction) and may be connected to the pixels PX located in the same column.

The display driver DDC may include a gate driver 22, a data driver 23, a timing controller 24, and a voltage generator 25.

Each of the scan lines SL_1 to SL_m transfers scan signals Sn_1 to Sn_m to the pixels PX in the same row, wherein the scan signals Sn_1 to Sn_m are output from the gate driver 22. Each of the data lines DL_1 to DL_n transfers data signals Dm_1 to Dm_n to the pixels PX in the same column, wherein the data signals Dm_1 to Dm_n are output from the data driver 23. The pixel PXij located in the i-th row and the j-th column receives a scan signal Sn_i and a data signal Dm_j.

The power lines PL transfer a first power voltage VDD to the pixels PX, wherein the first power voltage VDD is output from the voltage generator 25.

The pixel PXij includes a light-emitting element and a driving transistor configured to control the magnitude of a current flowing through the light-emitting element based on a data signal Dm_j. A data signal Dm_j is output from the data driver 23 and received by the pixel PXij through a data line DL_j. The light-emitting element may be, for example, an organic light-emitting diode (OLED). Because the light-emitting element emits light at a brightness corresponding to the magnitude of a current received from the driving transistor, the pixel PXij may express a grayscale corresponding to a data signal Dm_j.

The voltage generator 25 may generate voltages required to drive the pixel PXij. As an example, the voltage generator 25 may generate the first power voltage VDD and a second power voltage VSS. A level of the first power voltage VDD may be greater than a level of the second power voltage VSS.

The voltage generator 25 may generate an initialization voltage and provide the initialization voltage to the pixels PX. The initialization voltage may be applied to a gate of the driving transistor and/or an anode of the light-emitting element.

In addition, the voltage generator 25 may generate a turn-on voltage and a turn-off voltage for controlling a switching transistor of the pixel PXij and provide the voltages to the gate driver 22. When a turn-on voltage is applied to a gate of the switching transistor, the switching transistor may be turned on, and when a turn-off voltage is applied to the gate of the switching transistor, the switching transistor may be turned off. The voltage generator 25 may generate gamma reference voltages and provide the same to the data driver 23.

The timing controller 24 may control the pixels PX by controlling operation timing of the gate driver 22 and the data driver 23. The pixels PX of the display layer 200 may display an image corresponding to image source data RGB of one frame by receiving a new data signal Dm and emitting light at a brightness corresponding to the data signal Dm for each frame period.

The timing controller 24 receives image source data RGB and a display control signal CONT from the outside. The timing controller 24 may convert image source data RGB into image data DATA based on electrical characteristics and/or the like of the display layer 200. The timing controller 24 may provide image data DATA to the data driver 23.

A display control signal CONT may include a vertical synchronization signal, a horizontal synchronization signal, a data enable signal, and a clock signal, and/or the like. The timing controller 24 may control operation timing of the gate driver 22 and the data driver 23 using a display control signal CONT. The timing controller 24 may determine a frame period by counting a data enable signal of a horizontal scanning period. Image source data RGB includes brightness information of the pixels PX. Brightness may have a fixed number of gray scales, for example, 1024 (=2¹⁰), 256 (=2⁸), or 64 (=2⁶).

The timing controller 24 may generate control signals including a gate timing control signal GCC for controlling operation timing of the gate driver 22, and a data timing control signal DCC for controlling operation timing of the data driver 23.

The gate driver 22 sequentially generates scan signals Sn_1 to Sn_m in response to a gate timing control signal GCC supplied from the timing controller 24 using a turn-on voltage or a turn-off voltage provided from the voltage generator 25.

The data driver 23 samples, latches image data DATA supplied from the timing controller 24 in response to a data timing control signal DCC supplied from the timing controller 24, and converts the image data DATA into data of a parallel data system. When converting image data DATA into data of a parallel data system, the data driver 23 converts the image data into a data signal Dm of an analog form by converting the image data DATA into a gamma reference voltage. The data driver 23 provides data signals Dm_1 to Dm_n to the pixels PX through the data lines DL_1 to DL_n. The pixels PX receive data signals Dm_1 to Dm_n in response to scan signals Sn_1 to Sn_m.

In one or more embodiments, the display driver DDC may be provided in the non-display area NDA of the display apparatus 1. The gate driver 22, the data driver 23, the timing controller 24, and the voltage generator 25 of the display driver DDC may be formed in separate integrated circuit (IC) chips, respectively, or formed in one integrated circuit (IC) chip, and may be disposed on a flexible printed circuit board (FPCB) electrically connected to a pad disposed on one side of the substrate.

In one or more embodiments, a portion or all of the gate driver 22 may be directly formed in the non-display area NDA of the display apparatus 1 during a process of forming the pixel driving circuit portion of the display area DA. The data driver 23, the timing controller 24, and the voltage generator 25 may be formed in separate integrated circuit (IC) chips, respectively, or formed in one integrated circuit (IC) chip, and may be disposed on the FPCB electrically connected to a pad disposed on one side of the substrate. In another embodiment, the data driver 23 and the timing controller 24 may be directly disposed on the substrate in a chip-on-plastic (COP) method.

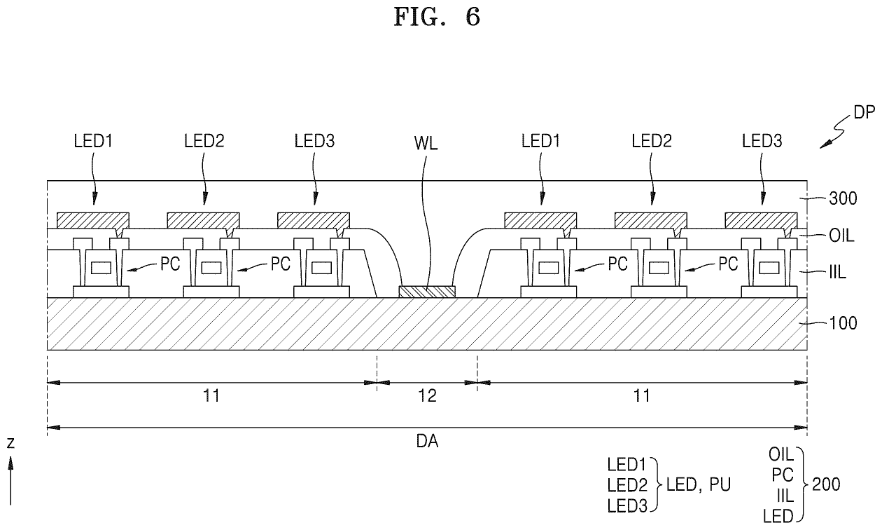

The strain sensor layer 600 may be disposed to overlap the display layer 200. The strain sensor layer 600 may overlap a plurality of light-emitting elements LED (see FIG. 6). The strain sensor layer 600 may include first sensing lines HSL extending in the first direction (x direction) and second sensing lines VSL extending in the second direction (y direction). Although FIG. 3 shows only one first sensing line HSL and one second sensing line VSL, at least two first sensing lines HSL and at least two second sensing lines VSL may be arranged. As an example, k first sensing lines HSL may be provided (k is a natural number greater than or equal to 2) and may be spaced (e.g., spaced apart) from each other in the second direction (y direction). “l” second sensing lines VSL may be provided (l is a natural number greater than or equal to 2) and may be spaced from each other in the first direction (x direction). The first sensing lines HSL and the second sensing lines VSL may cross each other in the display area DA (see FIG. 1) and form a mesh structure in a plan view. Electrical characteristics of the first sensing lines HSL and the second sensing lines VSL may change depending on stretching of the display panel DP. A change in electrical characteristics may include a change in a voltage and/or current of each of the first sensing lines HSL and the second sensing lines VSL.

The stretching compensation portion SCC may measure electrical characteristics of each of the first sensing lines HSL and the second sensing lines VSL, compare the electrical characteristics with a reference value to generate comparative data, generate stretching compensation data SCD and/or protective control signal PCS based on the comparative data, and transfer the same to the display driver DDC.

The comparative data may have one of two values by comparing a characteristic value (e.g., measurement voltage) with a corresponding reference value (e.g., reference voltage) for each of the first sensing lines HSL and the second sensing lines VSL. As an example, when a characteristic value of one of the first sensing line HSL and the second sensing line VSL is equal to or less than a reference value, comparative data may have a first value (e.g., a low-level voltage) for the sensing line. When a characteristic value of one of the first sensing line HSL and the second sensing line VSL is greater than the reference value, comparative data may have a second value (e.g., a high-level voltage) for the sensing line.

The stretching compensation portion SCC may divide the display area DA into a plurality of sub-regions, and generate stretching compensation data SCD compensating for image data DATA on a sub-region basis based on comparative data. Compensating for image data DATA on a sub-region basis means selecting a sub-region requiring compensation due to stretching, and changing data signals of pixels included in the selected sub-region based on the image data DATA and stretching compensation data SCD in order to compensate for the brightness and/or color coordinates of the pixels included in the selected sub-region. The stretching compensation portion SCC may select a look-up table corresponding to comparative data from among a plurality of look-up tables stored in a memory in advance and generate stretching compensation data SCD based on the selected look-up table. In one or more embodiments, the look-up table may include gamma compensation values.

In one or more embodiments, the stretching compensation portion SCC may determine a stretching stage for each of the sub-regions based on comparative data and generate different stretching compensation data SCD according to the stretching stage. As an example, in a first stretching operation, the stretching compensation data SCD may include compensation values for compensating for color coordinates of stretched sub-regions. In a second stretching operation, the stretching compensation data SCD may include compensation values for compensating for brightness of stretched sub-regions of image data DATA. In a third stretching operation, the stretching compensation portion SCC may generate a protective control signal PCS for controlling the first power voltage VDD and/or the second power voltage VSS. In a fourth stretching operation, the stretching compensation portion SCC may generate a mechanism control signal for controlling the operation of a stretching mechanism portion that stretches the display apparatus 1. The step-by-step operation of the stretching compensation portion SCC is provided as an example, and the present disclosure is not limited thereto. As an example, some operations may be omitted and/or added, and in each operation, two or more operations may be concurrently (e.g., simultaneously) performed.

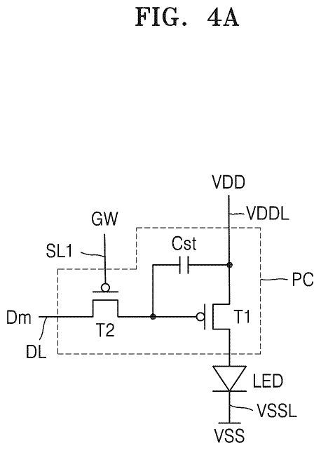

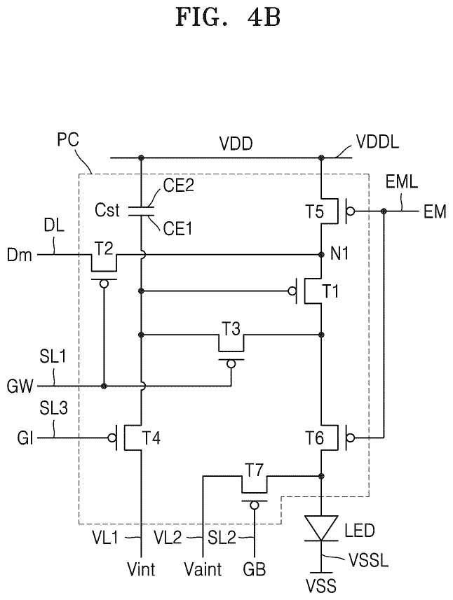

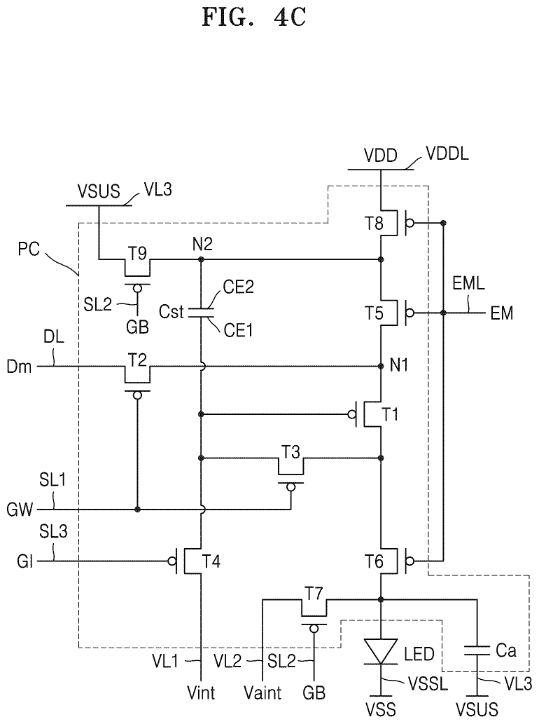

FIGS. 4A, 4B, and 4C are equivalent circuit diagrams of a pixel PX (see FIG. 3) included in the display apparatus 1 (see FIG. 3) according to one or more embodiments.

Referring to FIG. 4A, the pixel PX (see FIG. 3) may include the light-emitting element LED and a pixel driving circuit portion PC electrically connected to the light-emitting element LED. The pixel driving circuit portion PC may include a first transistor T1, a second transistor T2, and a storage capacitor Cst. The pixel driving circuit portion PC may be electrically connected to a signal line and a voltage line. The signal line may include a gate line such as a first scan line SL1, and a data line DL, and the voltage line may include the first voltage line (a driving power voltage line) VDDL. The first voltage line VDDL may be an element corresponding to the power line PL shown in FIG. 3.

The second transistor T2 may be electrically connected to the first scan line SL1 and the data line DL. The first scan line SL1 may provide a first scan signal GW to a gate electrode of the second transistor T2. The second transistor T2 may be a switching transistor turned on or turned off according to a first scan signal GW input from the first scan line SL1. The second transistor T2 may be electrically connected to the first transistor T1 and may transfer a data signal Dm input from the data line DL to the first transistor T1.

The storage capacitor Cst may be electrically connected to the second transistor T2 and the first voltage line VDDL and may store a voltage corresponding to a difference between a voltage transferred from the second transistor T2 and the first power voltage VDD supplied by the first voltage line VDDL.

The first transistor T1 is a driving transistor and may control a driving current flowing through the light-emitting element LED. The first transistor T1 may be connected between the first voltage line VDDL and the light-emitting element LED. The first transistor T1 may control the driving current flowing from the first voltage line VDDL to the light-emitting element LED in response to a voltage value stored in the storage capacitor Cst. The light-emitting element LED may emit light having a preset brightness based on the driving current. A first electrode (anode) of the light-emitting element LED may be electrically connected to the first transistor T1, and a second electrode (cathode) of the light-emitting element LED may be electrically connected to the second voltage line VSSL supplying the second power voltage (common power voltage) VSS.

Although it is shown in FIG. 4A that the pixel driving circuit portion PC includes two transistors and one storage capacitor, the pixel driving circuit portion PC may include three or more transistors in other embodiments.

Referring to FIG. 4B, the pixel driving circuit portion PC may include the first transistor T1, the second transistor T2, a third transistor T3, a fourth transistor T4, a fifth transistor T5, a sixth transistor T6, a seventh transistor T7, and a storage capacitor Cst. The pixel driving circuit portion PC is electrically connected to signal lines and voltage lines. The signal lines may include a gate line such as the first scan line SL1, a second scan line SL2, a third scan line SL3, and an emission control line EML, and the data line DL. The voltage lines may include a first initialization voltage line VL1, a second initialization voltage line VL2, the first voltage line VDDL, and the second voltage line VSSL.

The first voltage line VDDL may transfer the first power voltage VDD to the first transistor T1. The first initialization voltage line VL1 may be configured to transfer a first initialization voltage Vint to the pixel driving circuit portion PC, wherein the first initialization voltage Vint initializes the first transistor T1. The second initialization voltage line VL2 may be configured to transfer a second initialization voltage Vaint to the pixel driving circuit portion PC, wherein the second initialization voltage Vaint initializes the first electrode of the light-emitting element LED.

The first transistor T1 may be connected to the first voltage line VDDL through the fifth transistor T5 and electrically connected to the light-emitting element LED through the sixth transistor T6. The first transistor T1 serves as a driving transistor, and receives a data signal Dm and supplies the driving current to the light-emitting element LED according to a switching operation of the second transistor T2.

The second to seventh transistors T2, T3, T4, T5, T6, and T7 may be switching transistors that are turned on or turned off according to a gate-source voltage or a gate voltage thereof.

The second transistor T2 is a data-write transistor and is electrically connected to the first scan line SL1 and the data line DL. The second transistor T2 is electrically connected to the first voltage line VDDL through the fifth transistor T5. The second transistor T2 may be turned on according to a first scan signal GW transferred through the first scan line SL1 and may perform a switching operation of transferring a data signal Dm to a first node N1 connected to a first electrode of the first transistor T1, wherein the data signal Dm is transferred through the data line DL.

The third transistor T3 is electrically connected to the first scan line SL1 and electrically connected to the light-emitting element LED through the sixth transistor T6. The third transistor T3 may be connected between a gate electrode and a second electrode of the first transistor T1. The third transistor T3 may be turned on according to the first scan signal GW to diode-connect the first transistor T1, wherein the first scan signal GW is transferred through the first scan line SL1.

The fourth transistor T4 serves as a first initialization transistor and is electrically connected to the third scan line SL3 and the first initialization voltage line VL1. The fourth transistor T4 may be turned on according to a third scan signal GI to initialize a voltage of the gate electrode of the first transistor T1 by transferring the first initialization voltage Vint to the gate electrode of the first transistor T1, wherein the third scan signal GI is transferred through the third scan line SL3. The third scan signal GI may correspond to a first scan signal of another pixel driving circuit portion disposed in a previous row of the relevant pixel driving circuit portion PC.

The fifth transistor T5 may be an operation control transistor, and the sixth transistor T6 may be an emission control transistor. The fifth transistor T5 and the sixth transistor T6 may be electrically connected to an emission control line EML, concurrently (e.g., simultaneously) turned on according to an emission control signal EM transferred through the emission control line EML, and may form a current path such that the driving current flows in a direction from the first voltage line VDDL to the light-emitting element LED.

The seventh transistor T7 serves as a second initialization transistor and may be electrically connected to the second scan line SL2, the second initialization voltage line VL2, the sixth transistor T6, and the light-emitting element LED. The seventh transistor T7 is turned on according to a second scan signal GB transferred through the second scan line SL2, and is configured to transfer the second initialization voltage Vaint from the second initialization voltage line VL2 to a first electrode of the light-emitting element LED, thereby initializing the first electrode of the light-emitting element LED.

The storage capacitor Cst may include a first capacitor electrode CE1 and a second capacitor electrode CE2. The first capacitor electrode CE1 is electrically connected to the gate electrode of the first transistor T1, and the second capacitor electrode CE2 is electrically connected to the first voltage line VDDL. The storage capacitor Cst may maintain a voltage applied to the gate electrode of the first transistor T1 by storing and maintaining a voltage corresponding to a difference between voltages of two opposite ends of the gate electrode of the first transistor T1 and the first voltage line VDDL.

Referring to FIG. 4C, the pixel driving circuit portion PC may include the first transistor T1, the second transistor T2, the third transistor T3, the fourth transistor T4, the fifth transistor T5, the sixth transistor T6, the seventh transistor T7, an eighth transistor T8, a ninth transistor T9, the storage capacitor Cst, and an auxiliary capacitor Ca.

The pixel driving circuit portion PC is electrically connected to signal lines and voltage lines. The signal lines may include a gate line such as the first scan line SL1, the second scan line SL2, the third scan line SL3, and the emission control line EML, and the data line DL. The voltage lines may include the first and second initialization voltage lines VL1 and VL2, a sustain voltage line VL3, the first voltage line VDDL, and the second voltage line VSSL.

The first voltage line VDDL may transfer the first power voltage VDD to the first transistor T1. The first initialization voltage line VL1 may be configured to transfer the first initialization voltage Vint to the pixel driving circuit portion PC, wherein the first initialization voltage Vint initializes the first transistor T1. The second initialization voltage line VL2 may be configured to transfer a second initialization voltage Vaint to the pixel driving circuit portion PC, wherein the second initialization voltage Vaint initializes the first electrode of the light-emitting element LED. The sustain voltage line VL3 may provide a sustain voltage VSUS to a second node N2, for example, the second capacitor electrode CE2 of the storage capacitor Cst during an initialization section and the data-write section.

The first transistor T1 may be connected to the first voltage line VDDL through the fifth transistor T5 and the eighth transistor T8 and electrically connected to the light-emitting element LED through the sixth transistor T6. The first transistor T1 serves as a driving transistor, and may receive a data signal Dm and supply the driving current to the light-emitting element LED according to a switching operation of the second transistor T2.

The second to ninth transistors T2, T3, T4, T5, T6, T7, T8, and T9 may be switching transistors turned on or turned off according to a gate-source voltage or a gate voltage thereof.

The second transistor T2 is electrically connected to the first scan line SL1 and the data line DL and electrically connected to the first voltage line VDDL through the fifth transistor T5 and the eighth transistor T8. The second transistor T2 may be turned on according to a first scan signal GW transferred through the first scan line SL1 and may perform a switching operation of transferring a data signal Dm to the first node N1, wherein the data signal Dm is transferred through the data line DL.

The third transistor T3 is electrically connected to the first scan line SL1 and electrically connected to the light-emitting element LED through the sixth transistor T6. The third transistor T3 may be turned on according to the first scan signal GW to compensate for a threshold voltage of the first transistor T1 by diode-connecting the first transistor T1, wherein the first scan signal GW is transferred through the first scan line SL1.

The fourth transistor T4 is electrically connected to the third scan line SL3 and the first initialization voltage line VL1, turned on according to a third scan signal GI transferred through the third scan line SL3, and initializes a voltage of the gate electrode of the first transistor T1 by transferring the first initialization voltage Vint from the first initialization voltage line VL1 to the gate electrode of the first transistor T1. The third scan signal GI may correspond to a first scan signal of another pixel driving circuit portion disposed in a previous row of the relevant pixel driving circuit portion PC.

The fifth transistor T5, the sixth transistor T6, and the eighth transistor T8 may be electrically connected to the emission control line EML, concurrently (e.g., simultaneously) turned on according to an emission control signal EM transferred through the emission control line EML, and may form a current path such that the driving current flows in a direction from the first voltage line VDDL to the light-emitting element LED.

The seventh transistor T7 serves as a second initialization transistor and may be electrically connected to the second scan line SL2, the second initialization voltage line VL2, and the sixth transistor T6. The seventh transistor T7 is turned on according to a second scan signal GB transferred through the second scan line SL2, and is configured to transfer the second initialization voltage Vaint from the second initialization voltage line VL2 to the first electrode of the light-emitting element LED, thereby initializing the first electrode of the light-emitting element LED.

The ninth transistor T9 may be electrically connected to the second scan line SL2, the second capacitor electrode CE2 of the storage capacitor Cst, and the sustain voltage line VL3. The ninth transistor T9 is turned on according to the second scan signal GB transferred through the second scan line SL2 and may transfer the sustain voltage VSUS to the second node N2, for example, the second capacitor electrode CE2 of the storage capacitor Cst during the initialization section and the data-write section.

Each of the eighth transistor T8 and the ninth transistor T9 may be electrically connected to the second node N2, for example, the second capacitor electrode CE2 of the storage capacitor Cst. In one or more embodiments, during the initialization section and the data-write section, the eight transistor T8 may be turned off and the ninth transistor T9 may be turned on. During an emission section, the eight transistor T8 may be turned on and the ninth transistor T9 may be turned off. Because the sustain voltage VSUS is transferred to the second node N2 during the initialization section and the data-write section, uniformity (e.g., long range uniformity (LRU)) in brightness of the display apparatus depending on a voltage drop of the first voltage line VDDL may be improved.

The storage capacitor Cst may include the first capacitor electrode CE1 and the second capacitor electrode CE2. The first capacitor electrode CE1 is electrically connected to the gate electrode of the first transistor T1, and the second capacitor electrode CE2 is electrically connected to the eighth transistor T8 and the ninth transistor T9.

The auxiliary capacitor Ca may be electrically connected to the sixth transistor T6, the sustain voltage line VL3, and the first electrode of the light-emitting element LED. The auxiliary capacitor Ca may prevent a black brightness from rising when the sixth transistor T6 is turned off by storing and maintaining a voltage corresponding to a voltage difference between the first electrode of the light-emitting element LED and the sustain voltage line VL3 while the seventh transistor T7 and the ninth transistor T9 are turned on.

FIGS. 5A and 5B are schematic cross-sectional views of the display apparatus 1 (see FIG. 1) shown in FIG. 1, taken along the line I-I′ of FIG. 1.

Referring to FIGS. 5A and 5B, the display apparatus 1 (see FIG. 1) may include the display panel DP. The display panel DP may include a first surface fs and a second surface bs facing the first surface fs. In the present specification, in the case where a first element is positioned closer to the first surface fs than a second element, it means that the first element is disposed on the second element, and in the case where the second element is positioned closer to the second surface bs than the first element, it means that the second element is disposed under the first element.

The display panel DP may include the substrate 100, a display layer 200, an encapsulation layer 300, a strain sensor layer 600, and a touch sensor layer 400.

The substrate 100 may be a stretchable substrate that may stretch and/or shrink in a desired direction (e.g., a preset direction). The substrate 100 may include a stretchable material, for example, stretchable polymer resin. In one or more embodiments, the substrate 100 may include elastomer. The elastomer may include an organic elastomer, an organic/inorganic elastomer, and/or a combination thereof. As an example, the substrate 100 may include a silicone-based elastomer such as polydimethylsiloxane, a styrene-based elastomer, an olefin-based elastomer, polyurethane, or a mixture thereof. The substrate 100 may have a single-layered structure or a multi-layered structure.

The display layer 200 may be disposed on the substrate 100. The display layer 200 may be a layer including a plurality of pixels PX (see FIG. 3) and configured to display images. The display layer 200 may include a pixel circuit layer PCL and a light-emitting element layer DEL on the pixel circuit layer PCL. The pixel circuit layer PCL may include the pixel driving circuit portion PC (see FIG. 4A-4C), the signal lines electrically connected to the pixel driving circuit portion PC, and outer circuits disposed in the non-display area NDA (see FIG. 1). The light-emitting element layer DEL may include light-emitting elements. In one or more embodiments, the light-emitting element may be a light-emitting diode (LED).

The encapsulation layer 300 sealing the light-emitting elements may be disposed on the display layer 200. In one or more embodiments, the encapsulation layer 300 may include a structure in which an inorganic encapsulation layer including an inorganic insulating material and an organic encapsulation layer including an organic insulating material are stacked. In another embodiment, the encapsulation layer 300 may include organic materials such as resin, urethane, epoxy, and/or acrylate. In another embodiment, the encapsulation layer 300 may include a photosensitive material, for example, a photoresist.

The strain sensor layer 600 may be disposed on the encapsulation layer 300. The strain sensor layer 600 may include sensing lines having electrical characteristics that change according to stretching of the display panel DP. In one or more embodiments, stretching of the display panel DP may be sensed by measuring the voltage of the sensing lines of the strain sensor layer 600. In one or more embodiments, stretching of the display panel DP may be sensed by measuring the current of the sensing lines of the strain sensor layer 600.

In one or more embodiments, the strain sensor layer 600 may be formed through a successive process with the encapsulation layer 300. As an example, the strain sensor layer 600 may be directly formed on a base surface provided by the encapsulation layer 300. In another embodiment, the strain sensor layer 600 may be attached to the encapsulation layer 300 using an adhesive layer and/or the like.

The touch sensor layer 400 may be disposed on the strain sensor layer 600. The touch sensor layer 400 may include touch electrodes, touch signal lines, and touch insulating layers disposed under and/or on the touch electrodes. The display apparatus may sense whether a user inputs a touch and a touch position by measuring an amount of change in a capacitance of the touch electrodes.

In one or more embodiments, the touch sensor layer 400 may be formed through a successive process with the strain sensor layer 600. As an example, the touch sensor layer 400 may be directly formed on a base surface provided by the strain sensor layer 600. In another embodiment, the touch sensor layer 400 may be configured as a separate panel and may be attached to the strain sensor layer 600 using an adhesive layer and/or the like.

Although it is shown in FIG. 5A that the strain sensor layer 600 is disposed between the encapsulation layer 300 and the touch sensor layer 400, the present disclosure is not limited thereto. As shown in FIG. 5B, the strain sensor layer 600 may be disposed on the rear surface of the substrate 100, for example, the second surface bs of the display panel DP. In another embodiment, the strain sensor layer 600 may be disposed between the substrate 100 and the display layer 200, or disposed on the touch sensor layer 400. In another embodiment, the strain sensor layer 600 may be integrally formed with the display layer 200 or the touch sensor layer 400. As an example, the sensing lines configuring the strain sensor may be disposed on the display layer 200 or some of conductive layers included in the touch sensor layer 400.

FIG. 6 is a schematic cross-sectional view of a portion of the display panel DP according to one or more embodiments.

Referring to FIG. 6, the display area DA may include a first region 11 and a second region 12, and the second region 12 may connect first regions 11 disposed adjacent to each other. The first region 11 may include the light-emitting element LED and a circuit for driving the light-emitting element LED, for example, the pixel driving circuit portion PC. The second region 12 may include a connection wiring WL included in a signal line supplying signals to each of the pixel driving circuit portions PC.

The first region 11 and the second region 12 may be formed on the substrate 100. In other words, the first region 11 and the second region 12 may be defined in the substrate 100. The light-emitting element LED and the pixel driving circuit portion PC may be disposed in the first region 11 of the substrate 100, and the connection wiring WL may be disposed in the second region 12 of the substrate 100.

The substrate 100 may absorb stress that may occur while the display panel DP is stretched. The substrate 100 may include an elastic polymer. For example, the substrate 100 may include at least one of thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, polydimethylsiloxane (PDMS), and/or ecoflex.

The display layer 200 may be disposed in the first region 11 of the substrate 100. The display layer 200 may include an inorganic insulating layer IIL, the pixel driving circuit portion PC, an organic insulating layer OIL, and the light-emitting element LED. The pixel driving circuit portion PC may be disposed on the substrate 100, and the inorganic insulating layer IIL may be disposed between electrodes included in the pixel driving circuit portion PC. The organic insulating layer OIL may be disposed on the inorganic insulating layer IIL to cover the pixel driving circuit portion PC. The light-emitting element LED may be disposed on the organic insulating layer OIL and electrically connected to the pixel driving circuit portion PC corresponding thereto. The inorganic insulating layer IIL may include an inorganic insulating material such as silicon nitride and/or silicon oxide, and the organic insulating layer OIL may include an organic insulating material such as polyimide.

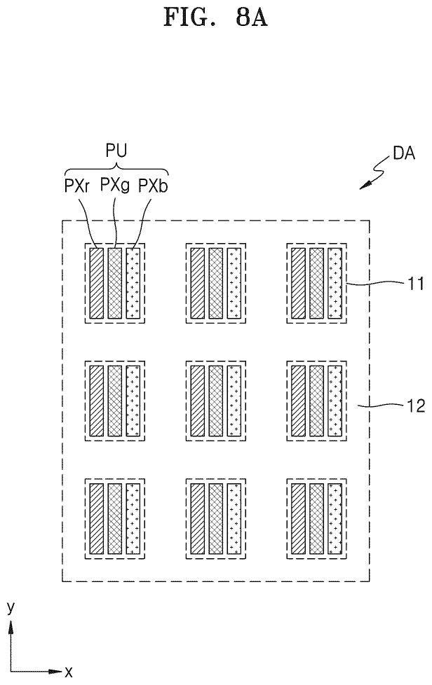

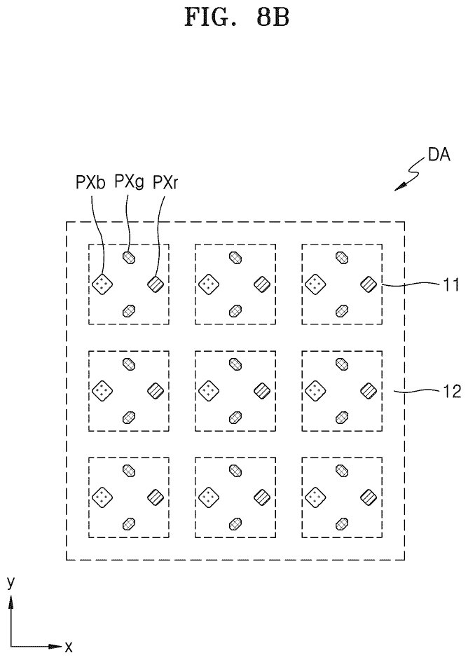

In one or more embodiments, one unit pixel PU may be disposed in one first region 11. The unit pixel PU may include a red pixel PXr (see FIG. 8A), a green pixel PXg (see FIG. 8A), and a blue pixel PXb (see FIG. 8A). The red pixel PXr (see FIG. 8A) may include a first light-emitting element LED1, the green pixel PXg (see FIG. 8A) may include a second light-emitting element LED2, and the blue pixel PXb (see FIG. 8A) may include a third light-emitting element LED3. As an example, the first light-emitting element LED1 may emit red light, the second light-emitting element LED2 may emit green light, and the third light-emitting element LED3 may emit blue light. In one or more embodiments, the light-emitting element LED may emit white light.

The connection wiring WL may be disposed in the second region 12 of the substrate 100. In one or more embodiments, as shown in FIG. 6, the connection wiring WL may be disposed on the substrate 100. In another embodiment, the connection wiring WL may be disposed inside the substrate 100. The connection wiring WL may include a material having both high stretchability and high electrical characteristics. In one or more embodiments, the connection wirings disposed in the second region 12 may include a liquid metal, but is not limited thereto. In another embodiment, the connection wirings WL may include a metal nano structure and an elastic polymer. In another embodiment, the connection wirings WL may include a conductive composite material including elastomer.

The organic insulating layer OIL may be disposed in the second region 12 of the substrate 100. In one or more embodiments, the organic insulating layer OIL disposed in the second region 12 may be a portion of the organic insulating layer OIL disposed in the first region 11 that extends to the second region 12. When the display panel DP is stretched, the second region 12 may be more transformed compared to the first region 11. Accordingly, unlike the first region 11, the second region 12 may not have a layer containing an inorganic insulating material that is prone to cracking.

In one or more embodiments, the encapsulation layer 300 may be disposed on the light-emitting element LED. The encapsulation layer 300 may be disposed in both the first region 11 and the second region 12. That is, the encapsulation layer 300 may be disposed to cover the display area DA entirely. The encapsulation layer 300 may cover the light-emitting element LED and the connection wiring WL. The encapsulation layer 300 may absorb stress that may occur while the display panel DP is stretched. Specifically, the encapsulation layer 300 may prevent stress from being transferred to the light-emitting element LED and the pixel driving circuit portion PC, wherein the stress may occur while the display panel DP is stretched.

The encapsulation layer 300 may include an elastic polymer. The encapsulation layer 300 may include thermoplastic polyurethane, silicone, thermoplastic rubbers, elastolefin, thermoplastic olefin, polyamide, polyether block amide, synthetic polyisoprene, polybutadiene, chloroprene rubber, butyl rubber, styrene-butadiene, epichlorohydrin rubber, polyacrylic rubber, silicone rubber, fluorosilicone rubber, fluoroelastomers, ethylene-vinyl acetate, and/or polydimethylsiloxane (PDMS).

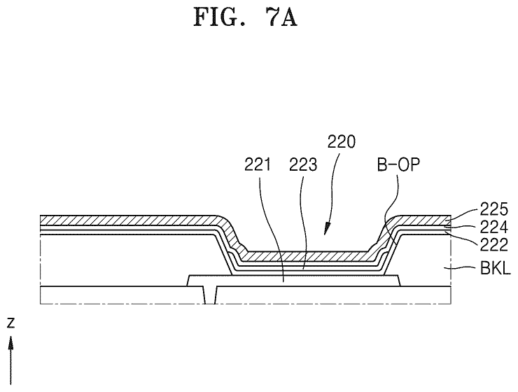

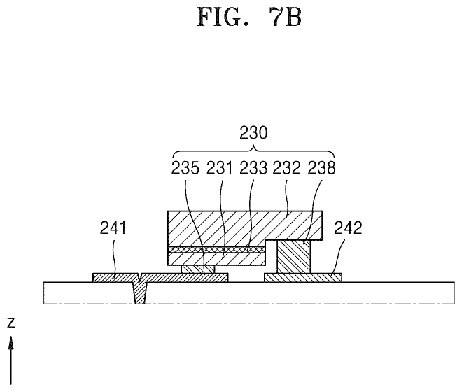

FIGS. 7A and 7B are schematic cross-sectional views of the light-emitting element LED (see FIG. 4A-4C) of the display apparatus 1 (see FIG. 3) according to one or more embodiments.

Referring to FIG. 7A, the light-emitting element according to one or more embodiments may be an organic light-emitting diode 220 including an organic material. The organic light-emitting diode 220 may include a first electrode 221 disposed on the insulating layer (e.g., the organic insulating layer OIL), a second electrode 225 facing the first electrode 221, and an emission layer 223 disposed between the first electrode 221 and the second electrode 225. A first functional layer 222 may be disposed between the first electrode 221 and the emission layer 223, and a second functional layer 224 may be disposed between the emission layer 223 and the second electrode 225.

The edge of the first electrode 221 may be covered by a bank layer BKL including an insulating material. The bank layer BKL may include an opening B-OP overlapping the central portion of the first electrode 221.

The first electrode 221 may include a conductive oxide such as indium tin oxide (ITO), indium zinc oxide (IZO), zinc oxide (ZnO), indium oxide (In₂O₃), indium gallium oxide (IGO), and/or aluminum zinc oxide (AZO). In another embodiment, the first electrode 221 may include a reflective layer including silver (Ag), magnesium (Mg), aluminum (Al), platinum (Pt), palladium (Pd), gold (Au), nickel (Ni), neodymium (Nd), iridium (Ir), chrome (Cr), and/or a compound thereof. In another embodiment, the first electrode 221 may further include a layer on/under the reflective layer, the layer including ITO, IZO, ZnO, AZO, and/or In₂O₃.

The emission layer 223 may include a polymer organic material or a low-molecular weight organic material emitting light having a suitable color (e.g., a preset color). The first functional layer 222 may include a hole transport layer (HTL) and/or a hole injection layer (HIL). The second functional layer 224 may include an electron transport layer and/or an electron injection layer.

The second electrode 225 may include a conductive material having a low work function. As an example, the second electrode 225 may include a (semi) transparent layer including silver (Ag), magnesium (Mg), aluminum (Al), platinum (Pt), palladium (Pd), gold (Au), nickel (Ni), neodymium (Nd), iridium (Ir), chrome (Cr), and/or an alloy thereof. Alternatively, the second electrode 225 may further include a layer on the (semi) transparent layer, the layer including ITO, IZO, ZnO, AZO, and/or In₂O₃.

Referring to FIG. 7B, the light-emitting element according to one or more embodiments may be an inorganic light-emitting diode 230 including an inorganic material. The inorganic light-emitting diode 230 may include a first semiconductor layer 231, a second semiconductor layer 232, an intermediate layer 233 between the first semiconductor layer 231 and the second semiconductor layer 232, a first electrode 235 electrically connected to the first semiconductor layer 231, and a second electrode 238 electrically connected to the second semiconductor layer 232. The first electrode 235 and the second electrode 238 of the inorganic light-emitting diode 230 may be respectively electrically connected to a first electrode pad 241 and a second electrode pad 242 disposed on (or at) the same layer.

In one or more embodiments, the first semiconductor layer 231 may include a p-type semiconductor layer. The p-type semiconductor layer may be selected from among semiconductor materials having a composition formula of InₓAl_{y}Ga_{1-x-y}N (0≤x≤1, 0≤y≤1, 0≤x+y≤1), such as GaN, AlN, AlGaN, InGaN, InN, InAlGaN, AlInN, and/or the like, and may be doped with a p-type dopant such as Mg, Zn, Ca, Sr, and/or Ba.

The second semiconductor layer 232 may include, for example, an n-type semiconductor layer. The n-type semiconductor layer may be selected from among semiconductor materials having a composition formula of InₓAl_{y}Ga_{1-x-y}N (0≤x≤1, 0≤y≤1, 0≤x+y≤1), such as GaN, AlN, AlGaN, InGaN, InN, InAlGaN, AlInN, and/or the like, and may be doped with an n-type dopant such as Si, Ge, and/or Sn.

The intermediate layer 233 is a region in which electrons and holes recombine, and when electrons and holes recombine, they transition to a lower energy level and light having a corresponding wavelength may be created. The intermediate layer 233 may include, for example, a semiconductor material having a composition formula of InₓAl_{y}Ga_{1-x-y}N (0≤x≤1, 0≤y≤1, 0≤x+y≤1), and may be formed in a single quantum-well structure or a multi quantum-well structure. In addition, the intermediate layer 233 may include a quantum-wire structure or a quantum-dot structure.

Although it is described in FIG. 7B that the first semiconductor layer 231 includes a p-type semiconductor layer and the second semiconductor layer 232 includes an n-type semiconductor layer, the present disclosure is not limited thereto. In another embodiment, the first semiconductor layer 231 may include an n-type semiconductor layer, and the second semiconductor layer 232 may include a p-type semiconductor layer.

FIGS. 8A and 8B are schematic plan views of a portion of the display area DA according to one or more embodiments.

Referring to FIGS. 8A and 8B, the display area DA may include the first regions 11 and the second region 12 between the first regions 11. The first region 11 may include at least one unit pixel PU. The unit pixel may be a minimum repeating unit of pixels having a suitable configuration (e.g., a preset configuration). In one or more embodiments, as shown in FIG. 8A, the pixels may be arranged in a stripe structure in the display area DA. One unit pixel PU may be disposed in the first region 11, and the unit pixel PU may include one red pixel PXr, one green pixel PXg, and one blue pixel PXb.

In one or more embodiments, as shown in FIG. 8B, the pixels may be arranged in a PENTILE® structure in the display area DA. The PENTILE® pixel arrangement structure may be referred to as an RGBG matrix structure (e.g., a PENTILE® matrix structure or an RGBG structure (e.g., a PENTILE® structure)). PENTILE® is a registered trademark of Samsung Display Co., Ltd., Republic of Korea. One unit pixel PU may be disposed in the first region 11, and the unit pixel PU may include one red pixel PXr, two green pixels PXg, and one blue pixel PXb.

Although it is shown in FIGS. 8A and 8B that the first region 11 has a quadrangular shape in a plan view, the first region 11 may have various polygonal shapes such as a hexagon, a circular shape, and/or the like. The second region 12 may be a region through which signal lines (e.g., a gate line, a data line, a voltage line, and/or the like) providing signals to the pixels disposed in the first regions 11 pass.

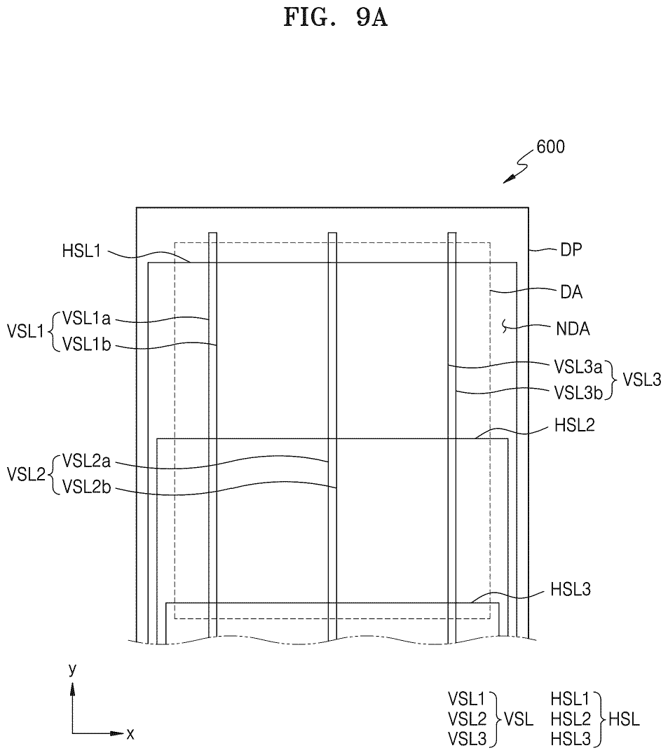

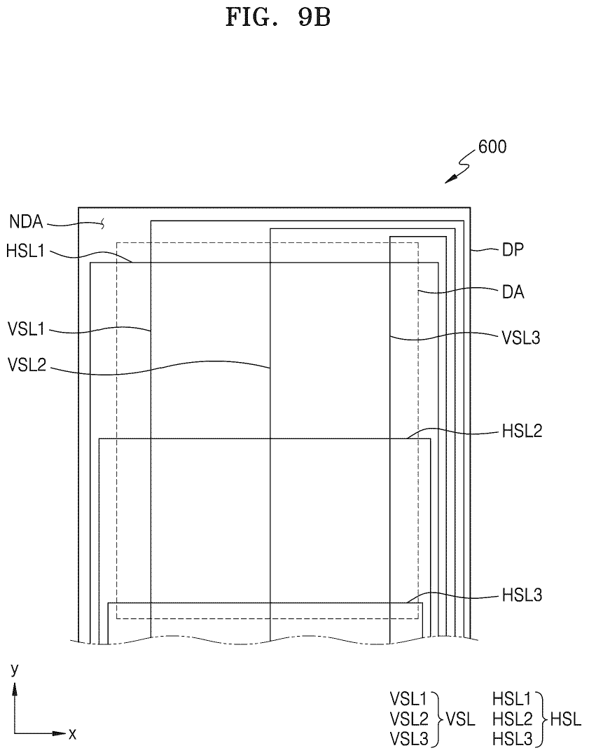

FIGS. 9A and 9B are schematic plan views of the strain sensor layer 600 according to one or more embodiments.

Referring to FIG. 9A, the display panel DP may include the strain sensor layer 600. The strain sensor layer 600 may include the first sensing lines HSL extending in the first direction (x direction) in the display area DA, and the second sensing lines VSL extending in the second direction (y direction) in the display area DA.

The first sensing lines HSL and the second sensing lines VSL may be provided in plurality. As an example, k first sensing lines HSL may be provided (k is a natural number equal to or greater than 2), and l second sensing lines VSL may be provided (l is a natural number equal to or greater than 2).

As an example, the first sensing line HSL may include a first-1 sensing line HSL1 crossing the upper region (+y side) of the display area DA in the first direction (x direction), a first-2 sensing line HSL2 crossing the central region in the first direction (x direction), and a first-3 sensing line HSL3 crossing the lower region (−y side) in the first direction (x direction). The second sensing line VSL may include a second-1 sensing line VSL1 crossing the left region (−x side) of the display area DA in the second direction (y direction), a second-2 sensing line VSL2 crossing the central region of the display area DA in the second direction (y direction), and a second-3 sensing line VSL3 crossing the right region (+x side) of the display area DA in the second direction (y direction). That is, three first sensing lines HSL and three second sensing lines VSL may be disposed in the display area DA.

In one or more embodiments, each of the second sensing lines VSL may include a pair of sub-sensing lines crossing the display area DA. As an example, as shown in FIG. 9A, the second-1 sensing line VSL1 may include a second-11 sub-sensing line VSL1a and a second-12 sub-sensing line VSL1b, the second-2 sensing line VSL2 may include a second-21 sub-sensing line VSL2a and a second-22 sub-sensing line VSL2b, and the second-3 sensing line VSL3 may include a second-31 sub-sensing line VSL3a and a second-32 sub-sensing line VSL3b. A pair of sub-sensing lines may be disposed adjacent to each other and connected to each other in the non-display area NDA.

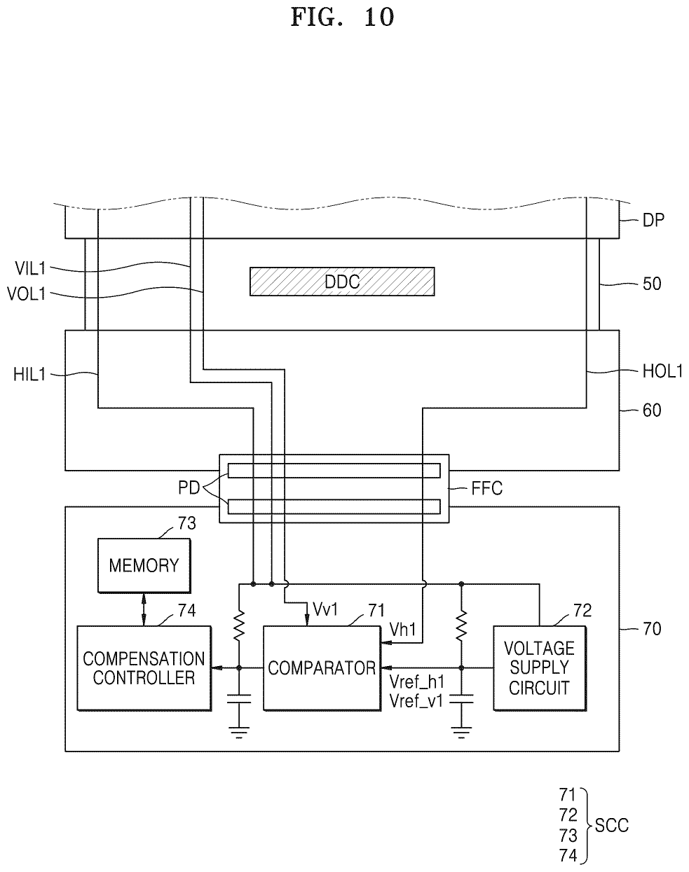

Although it is shown in FIG. 9A that each of the second sensing lines VSL includes a pair of sub-sensing lines and is disposed to cross the display area DA twice, the present disclosure is not limited thereto. Referring to FIG. 9B, each of the second sensing lines VSL may be disposed to cross the display area DA once. As an example, each of the second sensing lines VSL may include a first portion and a second portion, wherein the first portion is connected to a corresponding vertical input line VIL (e.g., see FIG. 10) and extends to the upper side (+y side) of the display panel DP to cross the display area DA, and the second portion is connected to corresponding vertical output lines VOL (e.g., see FIG. 10), detours the display area DA, and extends to the lower side (−y side) of the display panel DP along the non-display area NDA. Also, in one or more embodiments, each of the first sensing lines HSL may include a first portion and a second portion, wherein the first portion is connected to a corresponding horizontal input line HIL (e.g., see FIG. 10) and extends to the right region (+x side) of the display panel DP to cross the display area DA, and the second portion is connected to corresponding horizontal output lines HOL (e.g., see FIG. 10), detours the display area DA, and extends to the lower side (−y side) of the display panel DP along the non-display area NDA.

The first sensing lines HSL and the second sensing lines VSL may cross each other in the display area DA and form a mesh structure in a plan view. The first sensing lines HSL and the second sensing lines VSL may be disposed on different layers and electrically separated from each other by at least one insulating layer.

Although it is shown in FIGS. 9A and 9B that the strain sensor layer 600 includes three first sensing lines HSL and three second sensing lines VSL, the present disclosure is not limited thereto. The strain sensor layer 600 may include two first sensing lines HSL and two second sensing lines VSL, or include four first sensing lines HSL and two second sensing lines VSL. However, the number of sensing lines may be variously changed. In addition, the first sensing lines HSL and the second sensing lines VSL may be disposed more densely in vulnerable areas where stress due to stretching is concentrated, by taking into account a stretching direction and elongation of the display panel DP.

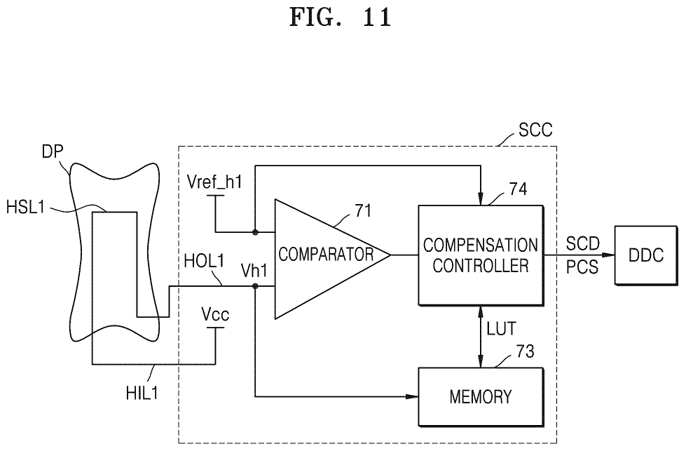

FIG. 10 is a schematic view of the strain sensor layer 600 (see FIG. 9A) and the stretching compensation portion SCC according to one or more embodiments, and FIG. 11 is a schematic view to explain an operation of the stretching compensation portion SCC according to one or more embodiments.

Referring to FIG. 10, the display apparatus 1 (see FIG. 3) may include the display panel DP, a first circuit board 50, a second circuit board 60, and a third circuit board 70 connected to the second circuit board 60 through a connector FFC.

The display panel DP may be electrically connected to the first circuit board 50 through a pad disposed on one side of the substrate. In one or more embodiments, the first circuit board 50 may be a flexible printed circuit board (FPCB) on which at least a portion of the display driver DDC is disposed. The first circuit board 50 may be electrically connected to the second circuit board 60 through a pad disposed on one side of the first circuit board 50. In one or more embodiments, the second circuit board 60 may be a printed circuit board (PCB).

Horizontal input lines, horizontal output lines, vertical input lines, and vertical output lines may be disposed on the first circuit board 50 and the second circuit board 60. For convenience of description, FIG. 10 shows only the first horizontal input line HIL1, the first horizontal output line HOL1, the first vertical input line VIL1, and the first vertical output line VOL1.

The first horizontal input line HIL1, the first horizontal output line HOL1, the first vertical input line VIL1, and the first vertical output line VOL1 may be connected to the stretching compensation portion SCC through the connector FFC connected to a pad portion PD disposed on one side of the second circuit board 60. The stretching compensation portion SCC may be disposed on the third circuit board 70.

The horizontal input lines may include the first horizontal input line HIL1 connected to the first-1 sensing line HSL1 (see FIG. 9A). One end of the first horizontal input line HIL1 may be connected to the stretching compensation portion SCC, and another end may be connected to the first-1 sensing line HSL1 to transfer a sensor driving voltage to the first-1 sensing line HSL1. The horizontal output lines may include the first horizontal output line HOL1 connected to the first-1 sensing line HSL1.

Because one end of the first horizontal output line HOL1 may be connected to the stretching compensation portion SCC, and another end may be connected to the first-1 sensing line HSL1, the stretching compensation portion SCC may measure a voltage of the first-1 sensing line HSL1.

The vertical input lines may include the first vertical input line VIL1 connected to the a second-11 sub-sensing line VSL1a (see FIG. 9A). One end of the first vertical input line VIL1 may be connected to the stretching compensation portion SCC, and another end may be connected to the second-11 sub-sensing line VSL1a to transfer a sensor driving voltage to the second-1 sensing line VSL1. The vertical output lines may include the first vertical output line VOL1 connected to the second-12 sub-sensing line VSL1b (see FIG. 9A). Because one end of the first vertical output line VOL1 may be connected to the stretching compensation portion SCC, and another end may be connected to the corresponding second sensing line VSL, the stretching compensation portion SCC may measure a voltage of the second-12 sub-sensing line VSL1b.

The unillustrated horizontal input lines, horizontal output lines, vertical input lines, and vertical output lines may have a connection relationship similar to the first horizontal input line HIL1, the first horizontal output line HOL1, the first vertical input line VIL1 and the first vertical output line VOL1, respectively.

Although it is shown in FIG. 10 that the first circuit board 50, the second circuit board 60, and the third circuit board 70 are separately provided, the present disclosure is not limited thereto. In one or more embodiments, the first circuit board 50, the second circuit board 60, and the third circuit board 70 may be integrally provided. As an example, the stretching compensation portion SCC may be mounted on the first circuit board 50, and the second circuit board 60, the connector FFC, and the circuit board 70 may be omitted. In another embodiment, the stretching compensation portion SCC may be mounted on the second circuit board 60, and the third circuit board 70 and the connector FFC may be omitted.

The stretching compensation portion SCC may include a comparator 71, a voltage supply circuit 72, a memory 73, and a compensation controller 74. The first horizontal input line HIL1 and the first vertical input line VIL1 may be electrically connected to the voltage supply circuit 72, and the first horizontal output line HOL1 and the first vertical output line VOL1 may be electrically connected to the comparator 71.

The voltage supply circuit 72 may supply reference voltages Vref_h1 and Vref_v1 of the first horizontal input line HIL1 and the first vertical input line VIL1, and a sensor driving voltage. In one or more embodiments, the voltage supply circuit 72 may supply the reference voltages Vref_h1 and Vref_v1 of the first horizontal input line HIL1 and the first vertical input line VIL1 differently according to the degree of stretching (or stretching stage) of the display panel DP. For this purpose, the voltage supply circuit 72 may be provided in a power control integrated circuit (IC) chip.

Referring to FIGS. 10 and 11 together, the comparator 71 compares two voltages input to a pair of input terminals and output an output voltage corresponding to a greater voltage of the two voltages. The comparator 71 may include a plurality of input terminal pairs including a first input terminal and a second input terminal.

A first input terminal pair may include a first input terminal and a second input terminal, wherein the first input terminal is electrically connected to the first horizontal output line HOL1, and the second input terminal is electrically connected to the voltage supply circuit 72. The voltage supply circuit 72 may supply the first horizontal reference voltage Vref_h1 to the second input terminal of the first input terminal pair. A voltage (referred to as a first horizontal measurement voltage Vh1, hereinafter) corresponding to electrical characteristics of the first-1 sensing line HSL1 measured through the first horizontal output line HOL1 may be different from a sensor driving voltage Vcc. As an example, in the case where the first-1 sensing line HSL1 is stretched in the first direction (x direction), a resistance of the first-1 sensing line HSL1 increases and the first horizontal measurement voltage Vh1 may be reduced. The first horizontal reference voltage Vref_h1 is a first horizontal measurement voltage at a point where a change in brightness or color coordinates due to stretching of the display panel DP is viewed to a user and stretching compensation is required, and may be stored in advance during the manufacturing process.

The comparator 71 compares the first horizontal measurement voltage Vh1 with the first horizontal reference voltage Vref_h1, outputs a first value to the compensation controller 74 when the first horizontal measurement voltage Vh1 is less than or equal to the first horizontal reference voltage Vref_h1, and outputs a second value to the compensation controller 74 when the first horizontal measurement voltage Vh1 is greater than the first horizontal reference voltage Vref_h1.

A second input terminal pair may include a third input terminal and a fourth input terminal, wherein the third input terminal is electrically connected to the first vertical output line VOL1, and the fourth input terminal is electrically connected to the voltage supply circuit 72. The voltage supply circuit 72 may supply the first vertical reference voltage Vref_v1 to the fourth input terminal of the second input terminal pair. A voltage (referred to as a first vertical measurement voltage Vv1, hereinafter) corresponding to electrical characteristics of the second-1 sensing line VSL1 measured through the first vertical output line VOL1 may be different from the sensor driving voltage Vcc. As an example, in the case where the second-1 sensing line VSL1 is stretched in the second direction (y direction), a resistance of the second-1 sensing line VSL1 increases and the first vertical measurement voltage Vv1 may be reduced. The first vertical reference voltage Vref_v1 is a first vertical measurement voltage at a point where a change in brightness or color coordinates due to stretching of the display panel DP is viewed to a user and stretching compensation is required, and may be stored in advance during the manufacturing process.

The comparator 71 compares the first vertical measurement voltage Vv1 with the first vertical reference voltage Vref_v1, outputs a first value to the compensation controller 74 when the first vertical measurement voltage Vv1 is less than or equal to the first vertical reference voltage Vref_v1, and outputs a second value to the compensation controller 74 when the first vertical measurement voltage Vv1 is greater than the first vertical reference voltage Vref_v1.

The memory 73 may store a plurality of look-up tables LUT and reference voltage information. The reference voltage information may include reference voltage values of each of the first sensing lines HSL (see FIG. 9A) and the second sensing lines VSL (see FIG. 9A). In one or more embodiments, the reference voltage information may include a plurality of reference voltage values according to a stretching stage of the display panel DP with respect to each of the first sensing lines HSL and the second sensing lines VSL. The voltage supply circuit 72 may supply a reference voltage of each of the first sensing lines HSL and the second sensing lines VSL to the comparator 71 based on the reference voltage information stored in advance in the memory 73.

The compensation controller 74 may generate comparative data based on output values of the comparator 71, selects a look-up table LUT corresponding to the comparative data from among a plurality of look-up tables LUT stored in advance in the memory 73, and generate stretching compensation data SCD based on the selected look-up table LUT. For this purpose, the compensation controller 74 may include a microprocessor (MPU), a microcontroller (MCU), and/or the like.

The comparative data may include output values of the comparator 71 for each of the first sensing lines HSL and the second sensing lines VSL. When the comparator 71 outputs a first value with respect to the first-1 sensing line HSL1, the compensation controller 74 may determine that at least a portion of the upper region (+y side) of the display area DA (see FIG. 11A) is stretched in the first direction (x direction) and stretching compensation is required. When the comparator 71 outputs a first value with respect to the second-1 sensing line VSL1, the compensation controller 74 may determine that at least a portion of the left region (−x side) of the display area DA (see FIG. 11A) is stretched in the second direction (y direction) and stretching compensation is required. When the comparator 71 outputs a first value with respect to the first-1 sensing line HSL1 and outputs a first value with respect to the second-1 sensing line VSL1, the compensation controller 74 may determine that the upper left region of the display area DA in which the first-1 sensing line HSL1 crosses the second-1 sensing line VSL1 is stretched in the first direction (x direction) and the second direction (y direction) or stretched in the third direction (z direction) and stretching compensation is required.

In one or more embodiments, the memory 73 may periodically store measurement voltage values of each of the first sensing lines HSL and measurement voltage values of each of the second sensing lines VSL. The compensation controller 74 may receive initial voltage information, measurement voltage values of each of the first sensing lines HSL and measurement voltage values of each of the second sensing lines VSL from the memory 73. Here, the initial voltage information may include measurement voltage values of each of the first sensing lines HSL and the second sensing lines VSL stored under an initial state before the display panel DP is stretched. The compensation controller 74 may determine a compensation intensity based on a difference between the measurement voltage values and initial voltage values. In this case, the compensation controller 74 may generate stretching compensation data including the compensation intensity.

Because the comparator 71 compares two input voltages fast and outputs a result thereof, the compensation controller 74 may fast determine a region for which compensation is required by using comparative data, and select a look-up table LUT corresponding thereto. Accordingly, the display apparatus according to one or more embodiments may prevent or reduce a change in image quality due to stretching from being viewed to a user by correcting images in real-time while stretching is performed and/or stretching ends.

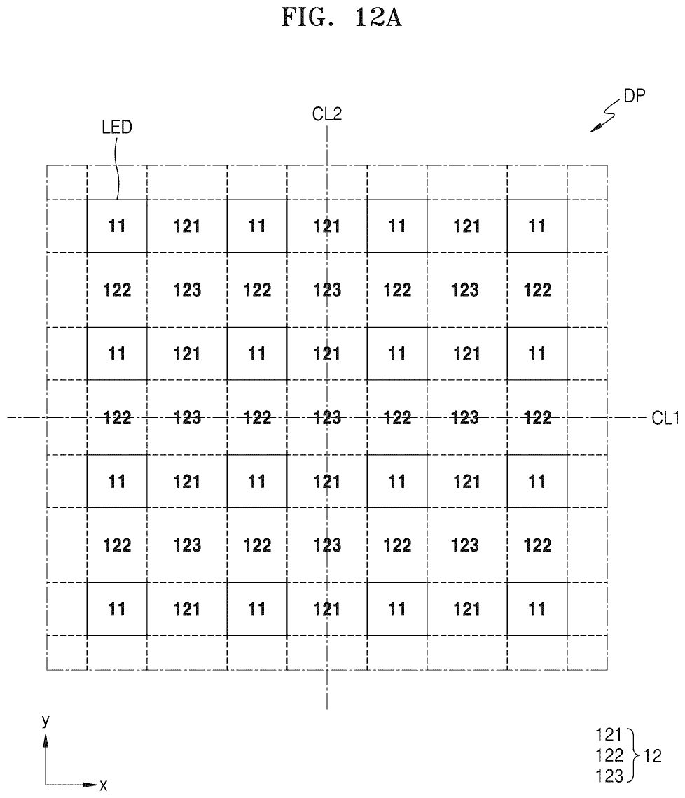

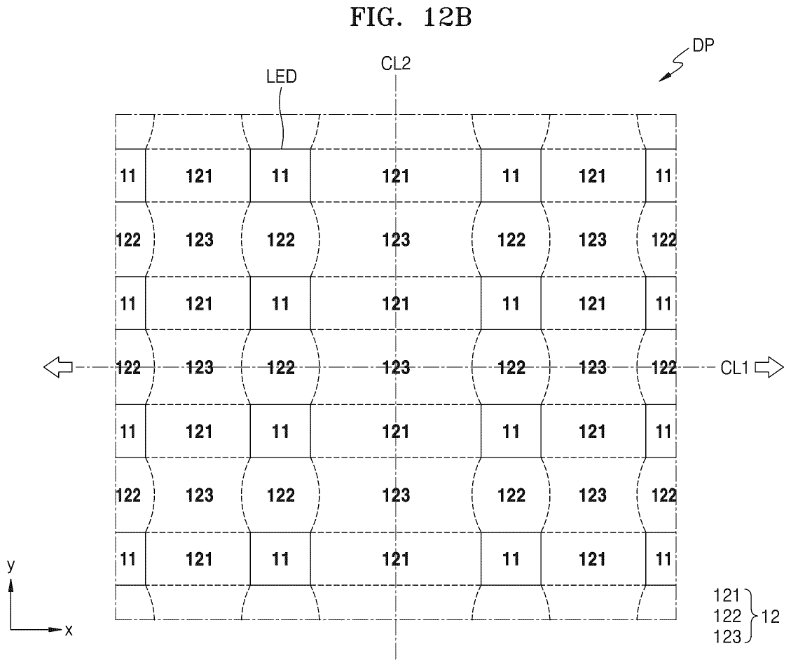

FIGS. 12A and 12B are schematic plan views of a portion of the display panel DP according to an embodiment.

Specifically, FIG. 12A is a plan view of a portion of the display area DA (see FIG. 1) before the display panel DP is stretched, and FIG. 12B is a plan view of a portion of the display area DA (see FIG. 1) after the display panel DP is stretched in the first direction (e.g., x direction and/or −x direction).

Referring to FIGS. 12A and 12B, the display panel DP may include a plurality of first regions 11 and second regions 12.

Referring to FIG. 12A, the plurality of first regions 11 may be spaced from each other in the first direction (e.g., x direction and/or −x direction) and the second direction (e.g., y direction and/or −y direction). The plurality of first regions 11 may be provided in an island type. The plurality of light-emitting elements LED may respectively overlap the plurality of first regions 11. In one first region 11, one corresponding light-emitting element LED may be disposed. The plurality of first regions 11 may be symmetrically disposed with respect to a first central line CL1 extending in the first direction (e.g., x direction and/or −x direction) and a second central line CL2 extending in the second direction (e.g., y direction and/or −y direction), which are virtual central lines of the display area DA (see FIG. 1). The plurality of first regions 11 may be disposed at equal intervals along the first direction (e.g., x direction and/or −x direction). The plurality of first regions 11 may be disposed at equal intervals along the second direction (e.g., y direction and/or −y direction). The plurality of first regions 11 may be disposed in a lattice configuration. The plurality of first regions 11 may be spaced from each of the first central line CL1 and the second central line CL2. However, this is just an example and the arrangement of the plurality of first regions 11 is not limited thereto.

The second region 12 may connect the plurality of first regions 11. The second region 12 may be provided to surround the plurality of first regions 11. The second region 12 may include a second-1 region 121, a second-2 region 122, and a second-3 region 123. A plurality of second-1 regions 121 may connect two first regions 11 that are spaced from each other in the first direction (e.g., x direction and/or −x direction) from among the plurality of first regions 11. A plurality of first regions 11 and a plurality of second-1 regions 121 may be alternately disposed along the first direction (e.g., x direction and/or −x direction). A plurality of second-2 regions 122 may connect two first regions 11 that area spaced from each other in the second direction (e.g., y direction and/or −y direction) from among the plurality of first regions 11. A plurality of first regions 11 and a plurality of second-2 regions 122 may be alternately disposed along the second direction (e.g., y direction and/or −y direction).

A plurality of second-3 regions 123 may be disposed between a plurality of second-1 regions 121 and a plurality of second-2 regions 122. The plurality of second-3 regions 123 may be surrounded by the plurality of second-1 regions 121 and the plurality of second-2 regions 122. The plurality of second-2 regions 122 and the plurality of second-3 regions 123 may be alternately disposed along the first direction (e.g., x direction and/or −x direction). The plurality of second-1 regions 121 and the plurality of second-3 regions 123 may be alternately disposed along the second direction (e.g., y direction and/or −y direction).

Referring to FIG. 12B, because the plurality of first regions 11 are regions in which the plurality of light-emitting elements LED are disposed, a modulus of the plurality of first regions 11 may be greater than a modulus of the second region 12. As an example, while the second region 12 is stretched, the plurality of first regions 11 may not be stretched. Moduli of the second-1 region 121, the second-2 region 122, and the second-3 region may be equal to each other.

While the display panel DP is stretched in the first direction (e.g., x direction and/or −x direction), a sum of a length by which the plurality of first regions 11 are stretched and a length by which the plurality of second-1 regions 121 are stretched may be equal to a sum of a length by which the plurality of second-2 regions 122 are stretched and a length by which the second-3 regions 123 are stretched. In this case, because a modulus of the plurality of first regions 11 is relatively large, a length by which the plurality of first regions 11 are stretched may be relatively small. Accordingly, a length by which the plurality of second-1 regions 121 are stretched may be relatively large. That is, from among the first region 11, the second-1 region 121, the second-2 region 122, and the second-3 region 123, a strain of the second-1 region 121 may be the largest.

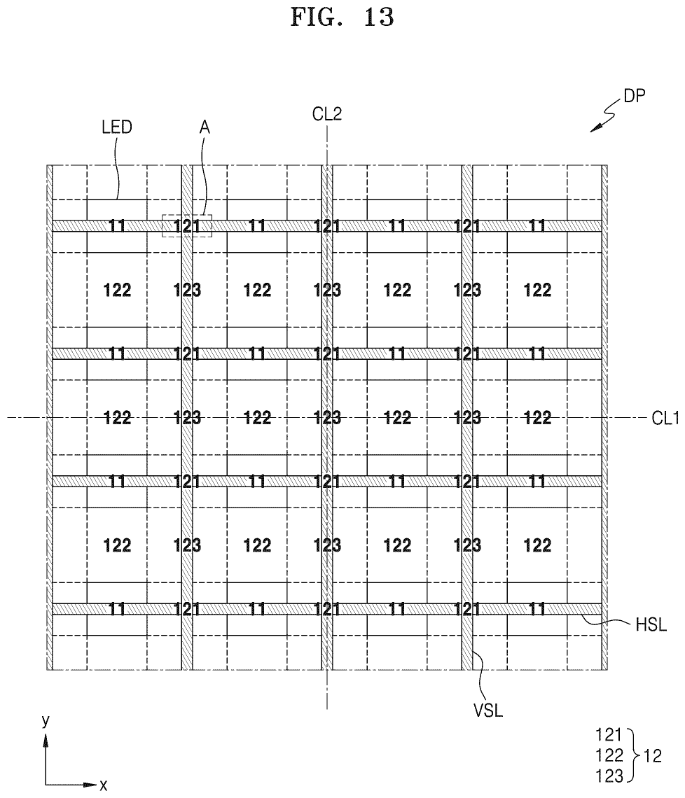

FIG. 13 is a schematic plan view of a portion of the display panel DP according to one or more embodiments.

In FIG. 13, the same reference numerals as those of FIG. 9A-12B denote the same members, and thus, repeated descriptions thereof are omitted.

Referring to FIG. 13, the strain sensor layer 600 (see FIG. 5A) may include the first sensing line HSL and the second sensing line VSL.

Each of the first sensing line HSL and the second sensing line VSL may sense stretching of the substrate 100 (see FIG. 5A) in the first direction (e.g., x direction and/or −x direction). Each of the first sensing line HSL and the second sensing line VSL may overlap the plurality of second-1 regions 121. In a plan view, the first sensing line HSL and the second sensing line VSL may cross the plurality of second-1 regions 121. The plurality of second-1 regions 121 may be a region in which strain is relatively large during a stretching process of the display panel DP. Because each of the first sensing line HSL and the second sensing line VSL is disposed in the plurality of second-1 regions 121, the first sensing line HSL and the second sensing line VSL may efficiently sense stretching of the display panel DP in the first direction (e.g., x direction and/or −x direction).

As an example, the first sensing line HSL may extend in the first direction (e.g., x direction and/or −x direction), and overlap each of the plurality of first regions 11 and the plurality of second-1 regions 121. The first sensing line HSL may overlap each of the plurality of first regions 11 and the plurality of second-1 regions 121 disposed in the same row. In a plan view, the first sensing line HSL may be spaced from each of the plurality of second-2 regions 122 and the plurality of second-3 regions 123. In a plan view, the first sensing line HSL may be provided in plurality. The plurality of first sensing lines HSL may be spaced from each other in the second direction (e.g., y direction and/or −y direction). The plurality of first sensing lines HSL may be disposed symmetrically with respect to the first central line CL1 and the second central line CL2.

As an example, the second sensing line VSL may extend in the second direction (e.g., y direction and/or −y direction), and overlap each of the plurality of second-1 regions 121 and the plurality of second-3 regions 123. The second sensing line VSL may overlap each of the plurality of second-1 regions 121 and the plurality of second-3 regions 123 disposed in the same column. In a plan view, the second sensing lines VSL may be spaced from each of the plurality of first regions 11 and the plurality of second-2 regions 122. The second sensing line VSL may be provided in plurality. In a plan view, the plurality of second sensing lines VSL may be spaced from each other in the first direction (e.g., x direction and/or −x direction). The plurality of second sensing lines VSL may be disposed symmetrically with respect to the first central line CL1 and the second central line CL2.

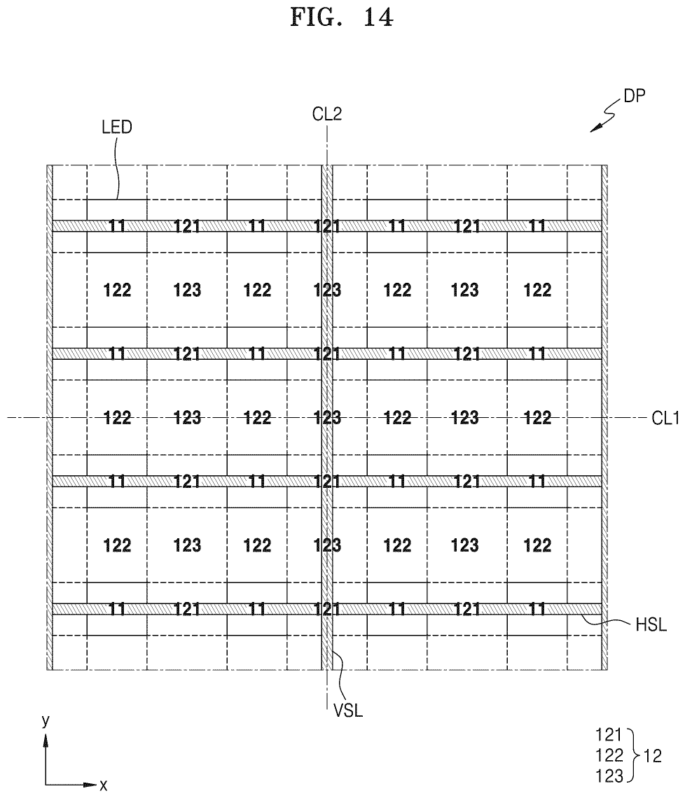

FIG. 14 is a schematic plan view of a portion of the display panel DP according to one or more embodiments.

In FIG. 14, the same reference numerals as those of FIG. 9A-12B denote the same members, and thus, repeated descriptions thereof are omitted.

Referring to FIG. 14, the strain sensor layer 600 (see FIG. 5A) may include the first sensing line HSL and the second sensing line VSL.

Each of the first sensing line HSL and the second sensing line VSL may sense stretching of the substrate 100 (see FIG. 5A) in the first direction (e.g., x direction and/or −x direction). Each of the first sensing line HSL and the second sensing line VSL may overlap the plurality of second-1 regions 121. In a plan view, the first sensing line HSL and the second sensing line VSL may cross the plurality of second-1 regions 121.

As an example, the first sensing line HSL may extend in the first direction (e.g., x direction and/or −x direction), and overlap each of the plurality of first regions 11 and the plurality of second-1 regions 121. The first sensing line HSL may overlap each of the plurality of first regions 11 and the plurality of second-1 regions 121 disposed in the same row. The first sensing line HSL may be provided in plurality. In a plan view, the plurality of first sensing lines HSL may be spaced apart from each other in the second direction (e.g., y direction and/or −y direction).

As an example, the second sensing line VSL may extend in the second direction (e.g., y direction and/or −y direction), and overlap each of the plurality of second-1 regions 121 and the plurality of second-3 regions 123. The second sensing line VSL may overlap each of the plurality of second-1 regions 121 and the plurality of second-3 regions 123 disposed in the same column. The second sensing line VSL may be provided in plurality. In a plan view, the plurality of second sensing lines VSL may be spaced from each other in the first direction (e.g., x direction and/or −x direction).

In a plan view, at least one of the plurality of second-1 regions 121 may be spaced from the plurality of second sensing lines VSL. In a plan view, at least one of the plurality of second-3 regions 123 may be spaced from the plurality of second sensing lines VSL. The plurality of second-1 regions 121 and the plurality of second-3 regions 123 disposed in one column may be spaced from the plurality of second sensing lines VSL in a plan view.

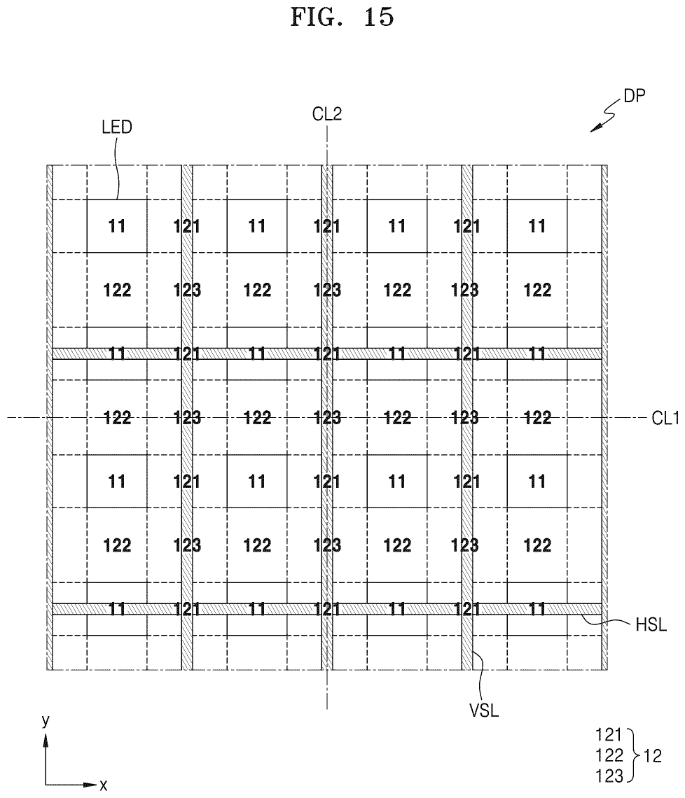

FIG. 15 is a schematic plan view of a portion of the display panel DP according to one or more embodiments.

In FIG. 15, the same reference numerals as those of FIG. 9A-12B denote the same members, and thus, repeated descriptions thereof are omitted.

Referring to FIG. 15, the strain sensor layer 600 (see FIG. 5A) may include the first sensing line HSL and the second sensing line VSL.

Each of the first sensing line HSL and the second sensing line VSL may sense stretching of the substrate 100 (see FIG. 5A) in the first direction (e.g., x direction and/or −x direction). Each of the first sensing line HSL and the second sensing line VSL may overlap the plurality of second-1 regions 121. In a plan view, the first sensing line HSL and the second sensing line VSL may cross the plurality of second-1 regions 121.

As an example, the first sensing line HSL may extend in the first direction (e.g., x direction and/or −x direction), and overlap each of the plurality of first regions 11 and the plurality of second-1 regions 121. The first sensing line HSL may overlap each of the plurality of first regions 11 and the plurality of second-1 regions 121 disposed in the same row. The first sensing line HSL may be provided in plurality. In a plan view, the plurality of first sensing lines HSL may be spaced from each other in the second direction (e.g., y direction and/or −y direction).

As an example, the second sensing line VSL may extend in the second direction (e.g., y direction and/or −y direction), and overlap each of the plurality of second-1 regions 121 and the plurality of second-3 regions 123. The second sensing line VSL may overlap each of the plurality of second-1 regions 121 and the plurality of second-3 regions 123 disposed in the same column. The second sensing line VSL may be provided in plurality. In a plan view, the plurality of second sensing lines VSL may be spaced from each other in the first direction (e.g., x direction and/or −x direction).

In a plan view, at least one of the plurality of first regions 11 may be spaced from the plurality of first sensing lines HSL. In a plan view, at least one of the plurality of second-1 regions 121 may be spaced from the plurality of first sensing lines HSL. The plurality of first regions 11 and the plurality of second-1 regions 121 disposed in one row may be spaced from the plurality of first sensing lines HSL in a plan view.

The embodiment described with reference to FIG. 13-15 is just an example, and the arrangement of the first sensing line HSL and the second sensing line VSL is not limited thereto. The first sensing line HSL and the second sensing line VSL may be concentrated on a region where strain is large when the display panel DP is stretched. Accordingly, the first sensing line HSL and the second sensing line VSL may efficiently sense stretching of the display panel DP. Alternatively, the first sensing line HSL and the second sensing line VSL may be concentrated on a region where strain is small when the display panel DP is stretched. Accordingly, the first sensing line HSL and the second sensing line VSL may complement sensing of stretching of a region of the display panel DP where strain is small.

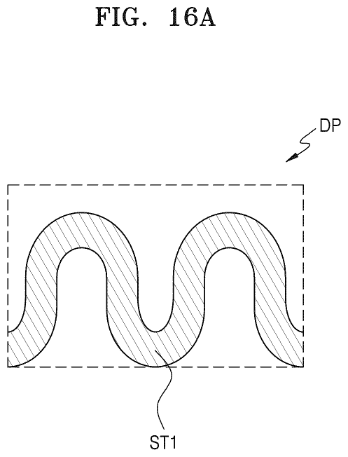

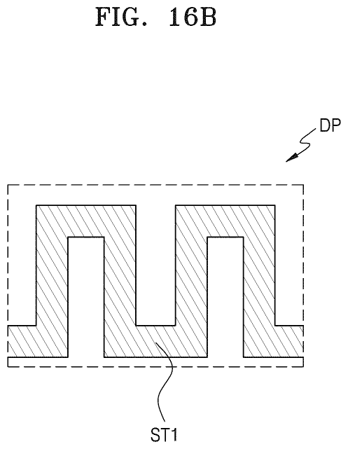

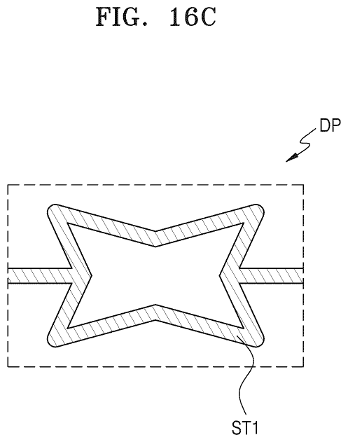

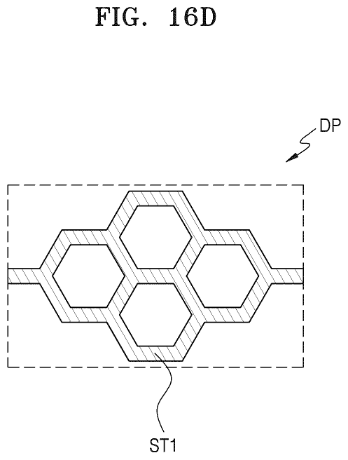

FIG. 16A-16D are schematic plan views of a portion of the display panel DP according to one or more embodiments.

Specifically, FIG. 16A-16D are enlarged views of a region A of FIG. 13.

In FIG. 16A-16D, the same reference numerals as those of FIG. 13 denote the same members, and thus, repeated descriptions thereof are omitted.

Referring to FIGS. 13, 16A-16D, in a region where the first sensing line HSL overlaps the second sensing line VSL, the first sensing line HSL may have a first structure ST1 efficiently sensing stretching of the substrate 100 (see FIG. 5A). The first structure ST1 may be disposed in the second-1 region 121 where strain is large while the display panel DP is stretched. Accordingly, the first structure ST1 may efficiently sense strain of the display panel DP.

As an example, the first structure ST1 may have a serpentine shape of a curve type as shown in FIG. 16A. As an example, the first structure ST1 may have a sinusoidal wave shape. As an example, the first structure ST1 may have a serpentine shape of a straight line-type (e.g., a square wave like shape) as shown in FIG. 16B. As an example, the first structure ST1 may have a square wave shape. As an example, the first structure ST1 may have a polygonal shape as shown in FIG. 16C. As an example, the first structure ST1 may include an octagonal shape with alternating obtuse and/or acute angles. As an example, the first structure ST1 may include a honeycomb shape as shown in FIG. 16D. As an example, the first structure ST1 may include a shape in which four octagons are combined to each other. However, this is just an example, and as far as the first structure ST1 has a structure that may sensitively sense strain, the first structure ST1 is not limited thereto.

The first structure ST1 may be disposed in at least one point where the first sensing line HSL crosses the second sensing line VSL. As an example, the first structure ST1 may be disposed in each of points where the first sensing line HSL crosses the second sensing line VSL. Alternatively, the first structure ST1 may be disposed in some of points where the first sensing line HSL crosses the second sensing line VSL. The first structure ST1 may be variously disposed at a position that should sensitively sense strain of the substrate 100 (see FIG. 5A) depending on a design condition of the display panel DP. In addition, likewise, the second sensing line VSL may also include the first structure ST1 that efficiently senses stretching of the substrate 100 (see FIG. 5A) in a region where the first sensing line HSL overlaps the second sensing line VSL.

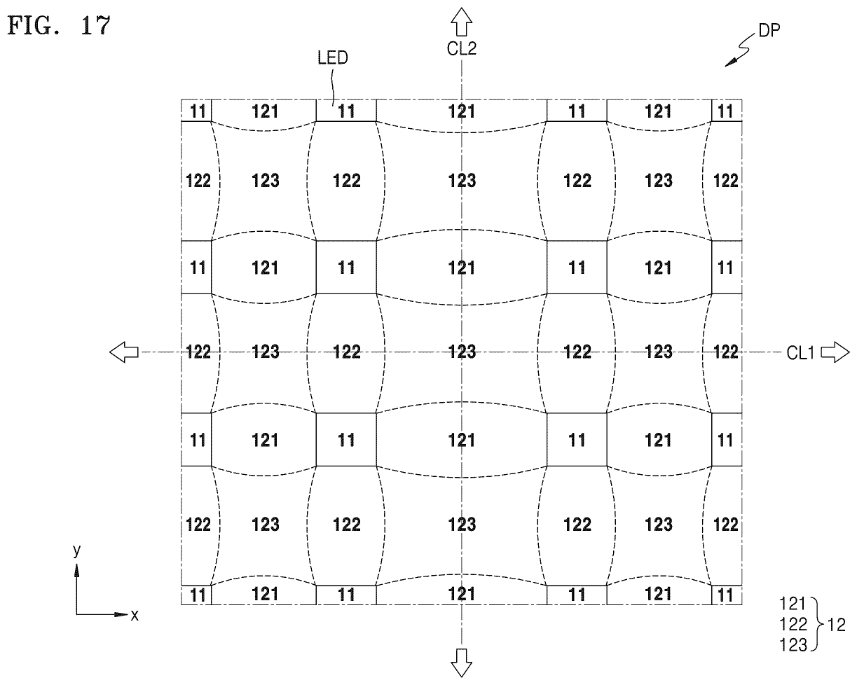

FIG. 17 is a schematic plan view of a portion of the display panel DP according to one or more embodiments.

Specifically, FIG. 17 is a plan view of the display area DA (see FIG. 1) after the display panel DP is stretched in the first direction (e.g., x direction and/or −x direction) and the second direction (e.g., y direction and/or −y direction).

In FIG. 17, the same reference numerals as those of FIG. 12A denote the same members, and thus, repeated descriptions thereof are omitted.

Referring to FIG. 17, because the plurality of first regions 11 are regions in which the plurality of light-emitting elements LED are disposed, a modulus of the plurality of first regions 11 may be greater than a modulus of the second region 12. As an example, while the second region 12 is stretched, the plurality of first regions 11 may not be stretched. Moduli of the second-1 region 121, the second-2 region 122, and the second-3 region 123 may be equal to each other.

While the display panel DP is stretched in the first direction (e.g., x direction and/or −x direction), a sum of a length by which the plurality of first regions 11 are stretched and a length by which the plurality of second-1 regions 121 are stretched may be equal to a sum of a length by which the plurality of second-2 regions 122 are stretched and a length by which the second-3 regions 123 are stretched. In this case, because a modulus of the plurality of first regions 11 is relatively large, a length by which the plurality of first regions 11 are stretched in the first direction (e.g., x direction and/or −x direction) may be relatively small. Accordingly, a length by which the plurality of second-1 regions 121 are stretched in the first direction (e.g., x direction and/or −x direction) may be relatively large. That is, from among the first region 11, the second-1 region 121, the second-2 region 122, and the second-3 region 123, a strain of the second-1 region 121 in the first direction (e.g., x direction and/or −x direction) may be the largest.

While the display panel DP is stretched in the second direction (e.g., y direction and/or −y direction), a sum of a length by which the plurality of first regions 11 are stretched and a length by which the plurality of second-2 regions 122 are stretched may be equal to a sum of a length by which the plurality of second-1 regions 121 are stretched and a length by which the second-3 regions 123 are stretched. In this case, because a modulus of the plurality of first regions 11 is relatively large, a length by which the plurality of first regions 11 are stretched in the second direction (e.g., y direction and/or −y direction) may be relatively small. Accordingly, a length by which the plurality of second-2 regions 122 are stretched in the second direction (e.g., y direction and/or −y direction) may be relatively large. That is, from among the first region 11, the second-1 region 121, the second-2 region 122, and the second-3 region 123, a strain of the second-2 region 122 in the second direction (e.g., y direction and/or −y direction) may be the largest.

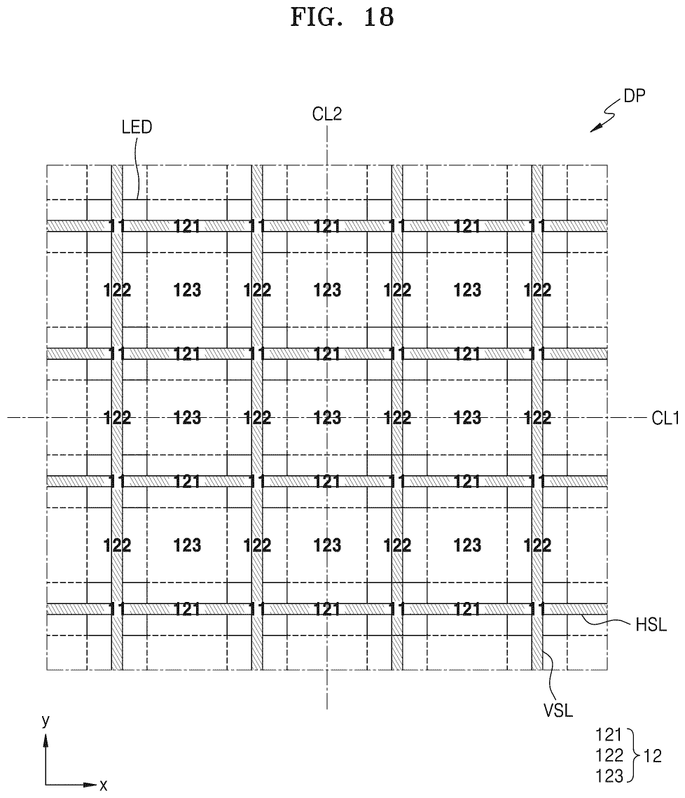

FIG. 18 is a schematic plan view of a portion of the display panel DP according to one or more embodiments.

In FIG. 18, the same reference numerals as those of FIGS. 12A and 17 denote the same members, and thus, repeated descriptions thereof are omitted.

Referring to FIG. 18, the strain sensor layer 600 (see FIG. 5A) may include the first sensing line HSL and the second sensing line VSL.

The first sensing line HSL may sense stretching of the substrate 100 (see FIG. 5A) in the first direction (e.g., x direction and/or −x direction). The first sensing line HSL may overlap the second-1 region 121. The plurality of second-1 region 121 may be a region in which strain is relatively large while the display panel DP is stretched in the first direction (e.g., x direction and/or −x direction). Because the first sensing line HSL is disposed in the plurality of second-1 regions 121, the first sensing line HSL may efficiently sense stretching of the display panel DP in the first direction (e.g., x direction and/or −x direction).

The second sensing line VSL may sense stretching of the substrate 100 (see FIG. 5A) in the second direction (e.g., y direction and/or −y direction). The second sensing line VSL may overlap the second-2 region 122. The plurality of second-2 region 122 may be a region in which strain is relatively large while the display panel DP is stretched in the second direction (e.g., y direction and/or −y direction). Because the second sensing line VSL is disposed in the plurality of second-2 regions 122, the second sensing line VSL may efficiently sense stretching of the display panel DP in the second direction (e.g., y direction and/or −y direction). With this structure, the first sensing line HSL and the second sensing line VSL may cross the plurality of first regions 11.

As an example, the first sensing line HSL may extend in the first direction (e.g., x direction and/or −x direction), and overlap each of the plurality of first regions 11 and the plurality of second-1 regions 121. The first sensing line HSL may overlap each of the plurality of first regions 11 and the plurality of second-1 regions 121 disposed in the same row. In a plan view, the first sensing line HSL may be spaced from each of the plurality of second-2 regions 122 and the plurality of second-3 regions 123. In a plan view, the first sensing line HSL may be provided in plurality. The plurality of first sensing lines HSL may be spaced from each other in the second direction (e.g., y direction and/or −y direction). The plurality of first sensing lines HSL may be disposed symmetrically with respect to the first central line CL1 and the second central line CL2.

As an example, the second sensing line VSL may extend in the second direction (e.g., y direction and/or −y direction), and overlap each of the plurality of first regions 11 and the plurality of second-2 regions 122. The second sensing line VSL may overlap each of the plurality of first regions 11 and the plurality of second-2 regions 122 disposed in the same column. In a plan view, the second sensing line VSL may be spaced from each of the plurality of second-1 regions 121 and the plurality of second-3 regions 123. The second sensing line VSL may be provided in plurality. In a plan view, the plurality of second sensing lines VSL may be spaced from each other in the first direction (e.g., x direction and/or −x direction). The plurality of second sensing lines VSL may be disposed symmetrically with respect to the first central line CL1 and the second central line CL2.

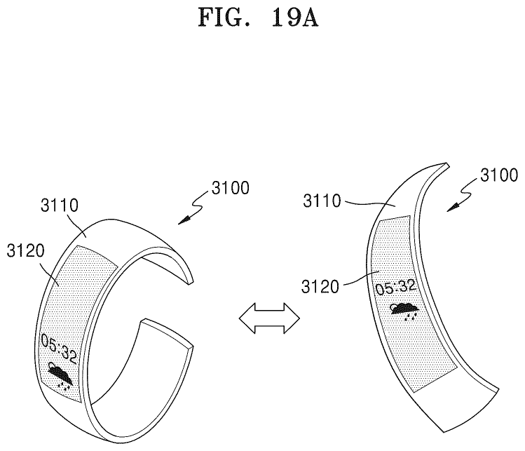

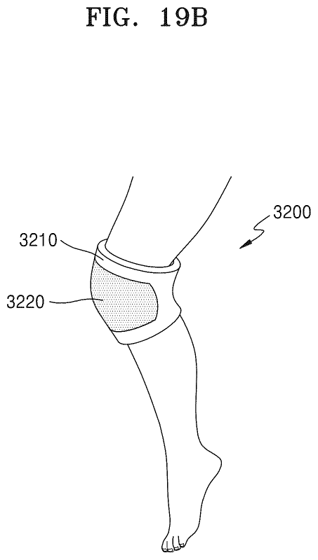

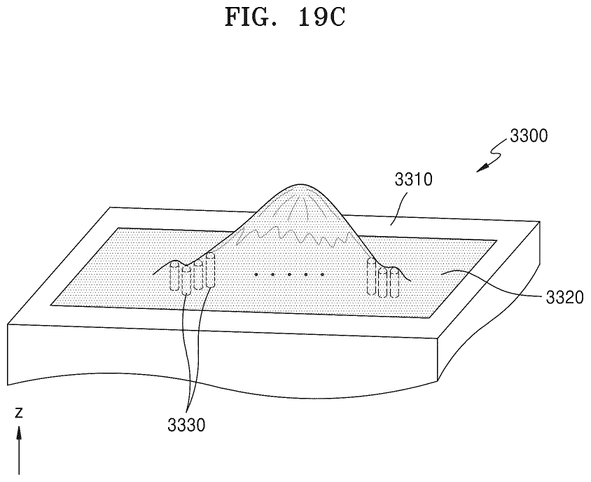

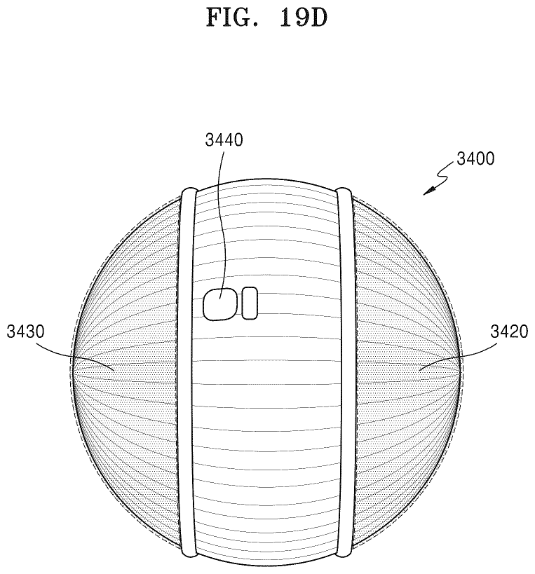

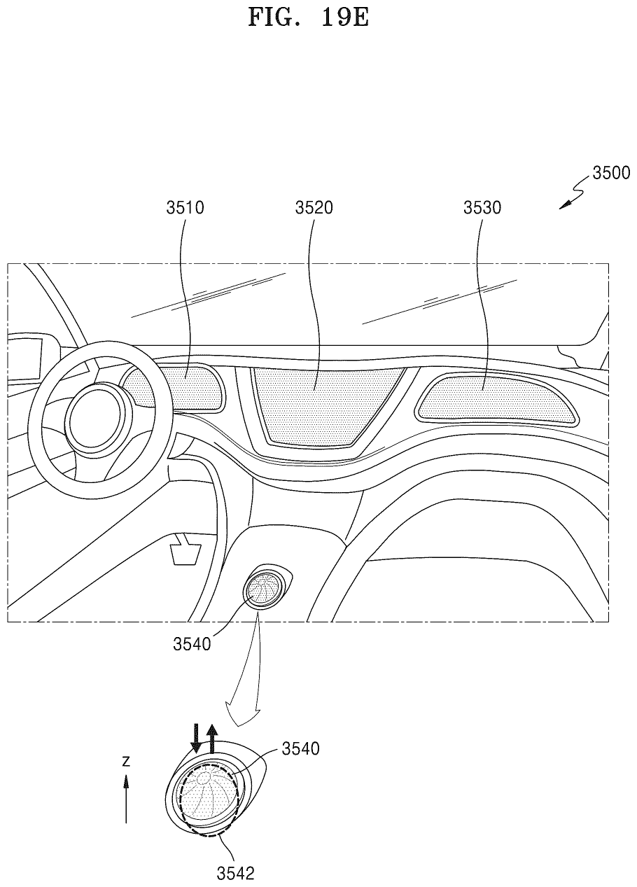

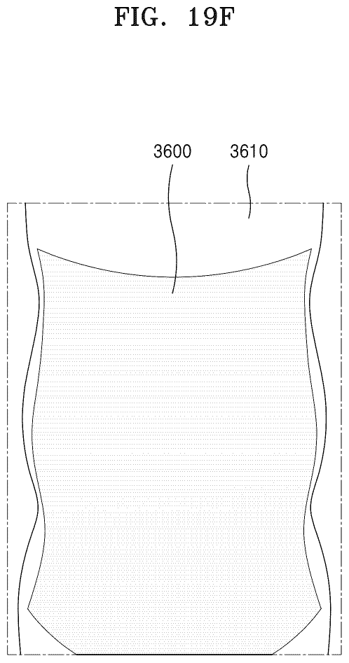

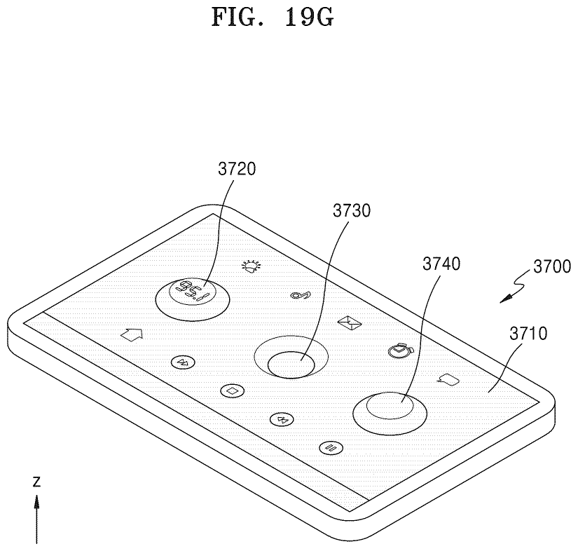

FIG. 19A-19G are schematic perspective views of electronic apparatuses including the display panel DP (see FIG. 3) according to one or more embodiments.

Referring to FIG. 19A, the display apparatus according to one or more embodiments may be utilized in a wearable electronic apparatus 3100 that may be worn on a portion of a user's body. The wearable electronic apparatus 3100 may include a body portion 3110 and a display portion 3120 provided to the body portion 3110. A stretchable display apparatus according to one or more embodiments may be used as a display portion 3120 of the wearable electronic apparatus 3100. As shown in FIG. 19A, the wearable electronic apparatus 3100 may be transformed. In one or more embodiments, the wearable electronic apparatus 3100 may be used as a smartwatch and/or a smartphone according to a user's selection.

FIG. 19B shows a medical electronic apparatus 3200. In one or more embodiments, the medical electronic apparatus 3200 may include a body portion 3210 and a light-emitting portion 3220. A stretchable display apparatus according to one or more embodiments may be used as the light-emitting portion 3220 of the medical electronic apparatus 3200. The light-emitting portion 3220 may emit light (e.g., infrared rays, visible rays, and/or the like) in a preset wavelength band to a patient's body. In one or more embodiments, the body portion 3210 may include a stretchable fiber material and have a structure that may be worn on the body of a user of the light-emitting portion.

FIG. 19C shows an educational electronic apparatus 3300. In one or more embodiments, the educational electronic apparatus may include a display portion 3320 provided inside a frame 3310. The display portion 3320 may be used as the stretchable display apparatus according to one or more embodiments. An image such as a sea with crashing waves, a snow-covered mountain, and/or a volcano with flowing lava can be provided through the display portion 3320, and in this case, the display portion 3320 may be stretched in a height direction (e.g., z direction) to reflect the height of the wave, mountain, and/or volcano. In one or more embodiments, a portion of the display portion 3320 may be configured to sequentially change its height in a direction in which the lava flows, thereby showing the movement of the lava three dimensionally. The educational electronic apparatus 3300 may include a plurality of pins 3330 (or a stroke portion) disposed on the rear surface of the display portion 3320 such that the display portion 3320 is stretched in the height direction. The pins 3330 may be implemented to move in the third direction (e.g., z direction or −z direction) such that an image expressed on the display portion 3320 has a height three dimensionally. Although FIG. 19C describes the educational electronic apparatus 3300, the purpose thereof is not limited thereto as far as the educational electronic apparatus 3300 provides suitable image information (e.g., preset image information).

Although FIG. 19A-19C describe an electronic apparatus having a variable shape, the present disclosure is not limited thereto. As in embodiments described below, the stretchable display apparatus according to one or more embodiments may be used in an electronic apparatus in which a portion (e.g., screen) that may display images is fixed.

FIG. 19D shows a robot 3400 as an electronic apparatus according to one or more embodiments. The robot 3400 may recognize a movement or object using a camera portion 3440 and express suitable images(e.g., preset images) to a user through display portions 3420 and 3430. In one or more embodiments, because the stretchable display apparatuses according to one or more embodiments may be stretched in various directions as described above, the stretchable display apparatuses may be assembled to a body frame having a hemispherical shape, and thus, the robot 3400 may include the display portions 3420 and 3430 of a hemispherical shape.

FIG. 19E shows a vehicle display apparatus 3500 as an electronic apparatus according to one or more embodiments. The vehicle display apparatus 3500 may include a cluster 3510, a center information display (CID) 3520, and/or a passenger display 3530. Because the stretchable display apparatus according to one or more embodiments may be stretched in various directions, the display apparatus may be used in the cluster 3510, the CID 3520, and/or the passenger display 3530 without being restricted by the shape of an internal frame of the vehicle.

Although it is shown in FIG. 19E that the cluster 3510, the CID 3520, and/or the passenger display 3530 are separated from each other, the present disclosure is not limited thereto. In another embodiment, two or more selected from the cluster 3510, the CID 3520, and the passenger display 3530 may be integrally connected.

In another embodiment, the vehicle display apparatus 3500 may include a button 3540 that may express suitable images (e.g., preset images). Referring to an enlarged view of FIG. 19E, the button 3540 of a hemispherical shape may include an object 3542 and a stretchable display apparatus disposed on the object 3542, wherein the object 3542 provides the feel of a button while moving in the z direction or −z-direction. In one or more embodiments, in the case where the object 3542 has a three-dimensionally round surface, the stretchable display apparatus may also have a three-dimensionally round surface.

FIG. 19F shows an electronic apparatus according to one or more embodiments is an electronic apparatus 3600 for advertising and/or display. In one or more embodiments, the electronic apparatus 3600 for advertising and/or display may be installed on a fixed structure 3610 such as a wall or pole. In the case where the structure 3610 includes an uneven surface as shown in FIG. 19F, the electronic apparatus 3600 for advertising or display may be also disposed along the uneven surface of the structure 3610. In one or more embodiments, the electronic apparatus 3600 for advertising and/or display may be installed on the structure 3610 using a heat shrink film.

FIG. 19G shows the electronic apparatus according to one or more embodiments is a controller 3700. The controller 3700 may include an image-type button. As an example, the controller 3700 may include first to third button regions 3720, 3730, and 3740 in which a portion of the display portion 3710 protrudes in the z direction or protrudes in the −z direction (or is recessed in the z direction). In one or more embodiments, the first and third button regions 3720 and 3740 may protrude in the z direction, and the second button region 3730 may protrude in the −z direction (or be recessed in the z direction).

According to one or more embodiments, the display apparatus having improved stretchability and configured to implement high-quality images, and an electronic apparatus including the display apparatus may be provided. The above effects, aspects, and features are just examples and are not limited thereto.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims and their equivalents.

What is claimed is:

1. A display apparatus including a plurality of first regions spaced from each other in a first direction and a second direction crossing the first direction, and a second region connecting the plurality of first regions, the display apparatus comprising:
a substrate;
a plurality of light-emitting elements over the substrate and overlapping the plurality of first regions; and
a strain sensor layer overlapping the plurality of light-emitting elements,
wherein the second region comprises:
a plurality of second-1 regions connecting two first regions of the plurality of first regions spaced from each other in the first direction; and
a plurality of second-2 regions connecting two first regions of the plurality of first regions spaced from each other in the second direction, and
wherein the strain sensor layer comprises a first sensing line configured to sense stretching of the substrate in the first direction, extending in the first direction, and overlapping each of the plurality of first regions and the plurality of second-1 regions.

2. The display apparatus of claim 1, wherein the first sensing line is spaced from the plurality of second-2 regions in a plan view.

3. The display apparatus of claim 1, wherein the plurality of first regions are located symmetrically with respect to a first central line extending in the first direction and a second central line extending in the second direction.

4. The display apparatus of claim 1, wherein the first sensing line comprises a plurality of first sensing lines, and at least one of the plurality of first regions is spaced from the plurality of first sensing lines in a plan view.

5. The display apparatus of claim 4, wherein the plurality of first sensing lines are located symmetrically with respect to a first central line extending in the first direction and a second central line extending in the second direction.

6. The display apparatus of claim 1, wherein the strain sensor layer further comprises a second sensing line configured to sense stretching of the substate in the first direction, extending in the second direction, and overlapping the plurality of second-1 regions.

7. The display apparatus of claim 6, wherein the second sensing line is spaced from each of the plurality of first regions and the plurality of second-2 regions in a plan view.

8. The display apparatus of claim 6, wherein the first sensing line and the second sensing line cross each other in the plurality of second-1 regions in a plan view.

9. The display apparatus of claim 6, wherein the second sensing line comprises a plurality of second sensing lines, and at least one of the plurality of second-1 regions is spaced from the plurality of second sensing lines in a plan view.

10. The display apparatus of claim 1, wherein the strain sensor layer further comprises a second sensing line configured to sense stretching of the substate in the second direction, extending in the second direction, and overlapping each of the plurality of first regions and the plurality of second-2 regions.

11. The display apparatus of claim 10, wherein the second sensing line is spaced from the plurality of second-1 regions in a plan view.

12. The display apparatus of claim 10, wherein the first sensing line and the second sensing line cross each other in the plurality of first regions in a plan view.

13. An electronic apparatus including a display apparatus including a plurality of first regions spaced from each other in a first direction and a second direction crossing the first direction, and a second region connecting the plurality of first regions, the electronic apparatus comprising:
a substrate;
a plurality of light-emitting elements over the substrate and overlapping the plurality of first regions; and
a strain sensor layer on the plurality of light-emitting elements,
wherein the second region comprises:
a plurality of second-1 regions connecting two first regions of the plurality of first regions spaced from each other in the first direction; and
a plurality of second-2 regions connecting two first regions of the plurality of first regions spaced from each other in the second direction,
wherein the strain sensor layer comprises:
a first sensing line configured to sense stretching of the substrate in the first direction and extending in the first direction; and
a second sensing line configured to sense stretching of the substrate in the first direction and extending in the second direction, and
wherein the first sensing line and the second sensing line cross each other in the plurality of second-1 regions.

14. The electronic apparatus of claim 13, wherein each of the first sensing line and the second sensing line is spaced from the plurality of second-2 regions.

15. The electronic apparatus of claim 13, wherein the first sensing line comprises a plurality of first sensing lines that are spaced from each other in the second direction, and the second sensing line comprises a plurality of second sensing lines that are spaced from each other in the first direction.

16. The electronic apparatus of claim 15, wherein at least one of the plurality of first regions is spaced from the plurality of first sensing lines in a plan view.

17. The electronic apparatus of claim 15, wherein at least one of the plurality of second-1 regions is spaced from the plurality of second sensing lines in a plan view.

18. An electronic apparatus including a display apparatus including a plurality of first regions spaced from each other in a first direction and a second direction crossing the first direction, and a second region connecting the plurality of first regions, the electronic apparatus comprising:
a substrate;
a plurality of light-emitting elements over the substrate and overlapping the plurality of first regions; and
a strain sensor layer on the plurality of light-emitting elements,
wherein the second region comprises:
a plurality of second-1 regions connecting two first regions of the plurality of first regions spaced from each other in the first direction; and
a plurality of second-2 regions connecting two first regions of the plurality of first regions spaced from each other in the second direction,
wherein the strain sensor layer comprises:
a first sensing line configured to sense stretching of the substrate in the first direction and extending in the first direction; and
a second sensing line configured to sense stretching of the substrate in the second direction and extending in the second direction, and
wherein the first sensing line and the second sensing line cross each other in the plurality of first regions.

19. The electronic apparatus of claim 18, wherein the second region further comprises a plurality of second-3 regions between the plurality of second-1 regions and the plurality of second-2 regions, and each of the first sensing line and the second sensing line is spaced from the plurality of second-3 regions.

20. The electronic apparatus of claim 18, wherein the first sensing line comprises a plurality of first sensing lines that are spaced from each other in the second direction, and the second sensing line comprises a plurality of the second sensing lines that are spaced from each other in the first direction.
